(19) United States
(12) Patent Application Publication
(10) Pub. No.: US 2026/0262307 A1
(43) Pub. Date: Sep. 3, 2026

(54) PHOTODETECTOR AND ELECTRONIC APPARATUS

(71) Applicant: SONY SEMICONDUCTOR SOLUTIONS CORPORATION, KANAGAWA (JP)

(72) Inventors: HIDEO KIDO, KANAGAWA (JP); TAKASHI MACHIDA, KANAGAWA (JP); RYOTO YOSHITA, KANAGAWA (JP); YU SHIIHARA, KANAGAWA (JP); DAIKI SAKAI, KANAGAWA (JP); YAMATO OGAWA, KANAGAWA (JP)

(21) Appl. No.: 19/164,737

(22) PCT Filed: Feb. 16, 2024
(86) PCT No.: PCT/JP2024/005551

§ 371 Date: Sep. 12, 2025

(30) Foreign Application Priority Data
Mar. 31, 2023 (JP) 2023-059433

(51) Int. Cl. H10F 39/00

(52) U.S. Cl. CPC H10F 39/8027; H10F 39/8057; H10F 39/807

(57) ABSTRACT

A photodetector according to an embodiment of the present disclosure includes a plurality of pixels and a separation part. The plurality of pixels includes a first pixel including a photoelectric converter provided in a semiconductor layer. The separation part is provided between the pixels adjacent to each other in the semiconductor layer. The first pixel includes a first transistor and a capacitor. The first transistor includes a first gate electrode, and is configured to transfer electric charge photoelectrically converted by the photoelectric converter. The first gate electrode is provided to reach the photoelectric converter in the semiconductor layer. The capacitor is provided to be stacked on the photoelectric converter, and is configured to accumulate the electric charge photoelectrically converted by the photoelectric converter. The first gate electrode is provided in a region away from the separation part in the semiconductor layer.

### TECHNICAL FIELD

The present disclosure relates to a photodetector and an electronic apparatus.

### BACKGROUND ART

An imaging device has been proposed that includes a sensor pixel including a photodiode, a transfer transistor, and an electric charge holding unit (PTL 1). The transfer transistor includes a vertical gate electrode. The electric charge holding unit holds eclectic charge transferred from the photodiode.

### CITATION LIST

### Patent Literature

PTL 1: Japanese Unexamined Patent Application Publication No. 2020-47616

### SUMMARY OF THE INVENTION

With regard to a device that detects light, it is required to suppress deterioration in signal quality.

It is desired to provide a photodetector configured to suppress deterioration in signal quality.

A photodetector according to an embodiment of the present disclosure includes a plurality of pixels and a separation part. The plurality of pixels includes a first pixel including a photoelectric converter provided in a semiconductor layer. The separation part is provided between the pixels adjacent to each other in the semiconductor layer. The first pixel includes a first transistor and a capacitor. The first transistor includes a first gate electrode, and is configured to transfer electric charge photoelectrically converted by the photoelectric converter. The first gate electrode is provided to reach the photoelectric converter in the semiconductor layer. The capacitor is provided to be stacked on the photoelectric converter, and is configured to accumulate the electric charge photoelectrically converted by the photoelectric converter. The first gate electrode is provided in a region away from the separation part in the semiconductor layer.

An electronic apparatus according to an embodiment of the present disclosure includes an optical system and a photodetector. The photodetector receives light transmitted through the optical system. The photodetector includes a plurality of pixels and a separation part. The plurality of pixels includes a first pixel including a photoelectric converter provided in a semiconductor layer. The separation part is provided between the pixels adjacent to each other in the semiconductor layer. The first pixel includes a first transistor and a capacitor. The first transistor includes a first gate electrode, and is configured to transfer electric charge photoelectrically converted by the photoelectric converter. The first gate electrode is provided to reach the photoelectric converter in the semiconductor layer. The capacitor is provided to be stacked on the photoelectric converter, and is configured to accumulate the electric charge photoelectrically converted by the photoelectric converter. The first gate electrode is provided in a region away from the separation part in the semiconductor layer.

### BRIEF DESCRIPTION OF THE DRAWINGS

FIG. 1 is a block diagram illustrating an example of a schematic configuration of an imaging device, which is an example of a photodetector according to an embodiment of the present disclosure.

FIG. 2 is a diagram illustrating an example of arrangement of pixels of the imaging device according to the embodiment of the present disclosure.

FIG. 3 is a diagram explaining an example of circuit configuration of the pixel of the imaging device according to the embodiment of the present disclosure.

FIG. 4 is a diagram illustrating an example of a cross-sectional configuration of the imaging device according to the embodiment of the present disclosure.

FIG. 5 is a diagram illustrating an example of a plan configuration of the pixel of the imaging device according to the embodiment of the present disclosure.

FIG. 6 is a diagram explaining an example of a configuration of the pixel of the imaging device according to the embodiment of the present disclosure.

FIG. 7 is a diagram explaining an example of the configuration of the pixel of the imaging device according to the embodiment of the present disclosure.

FIG. 8 is a diagram explaining an example of the configuration of the pixel of the imaging device according to the embodiment of the present disclosure.

FIG. 9 is a diagram explaining an example of the configuration of the pixel of the imaging device according to the embodiment of the present disclosure.

FIG. 10 is a diagram explaining another example of the configuration of the pixel of the imaging device according to the embodiment of the present disclosure.

FIG. 11 is a diagram explaining another example of the configuration of the pixel of the imaging device according to the embodiment of the present disclosure.

FIG. 12 is a diagram explaining another example of the configuration of the pixel of the imaging device according to the embodiment of the present disclosure.

FIG. 13A is a diagram explaining another example of the configuration of the pixel of the imaging device according to the embodiment of the present disclosure.

FIG. 13B is a diagram explaining another example of the configuration of the pixel of the imaging device according to the embodiment of the present disclosure.

FIG. 14 is a diagram explaining an example of a configuration of a pixel of an imaging device according to Modification example 1 of the present disclosure.

FIG. 15 is a diagram explaining an example of the configuration of the pixel of the imaging device according to Modification example 1 of the present disclosure.

FIG. 16A is a diagram explaining an example of a circuit configuration of the pixel of the imaging device according to Modification example 1.

FIG. 16B is a diagram explaining another example of the circuit configuration of the pixel of the imaging device according to Modification example 1.

FIG. 16C is a diagram explaining another example of the circuit configuration of the pixel of the imaging device according to Modification example 1.

FIG. 16D is a diagram explaining another example of the circuit configuration of the pixel of the imaging device according to Modification example 1.

FIG. 17 is a diagram explaining an example of a configuration of the pixel of the imaging device according to Modification example 2 of the present disclosure.

FIG. 18 is a diagram explaining an example of a configuration of the pixel of the imaging device according to Modification example 2 of the present disclosure.

FIG. 19 is a diagram explaining an example of the configuration of the pixel of the imaging device according to Modification example 2 of the present disclosure.

FIG. 20 is a diagram explaining an example of the configuration of the pixel of the imaging device according to Modification example 2 of the present disclosure.

FIG. 21 is a diagram explaining an example of a configuration of a pixel of an imaging device according to Modification example 3 of the present disclosure.

FIG. 22 is a diagram explaining an example of the configuration of the pixel of the imaging device according to Modification example 3 of the present disclosure.

FIG. 23 is a diagram illustrating an example of a circuit configuration of a pixel of an imaging device according to Modification example 4.

FIG. 24 is a block diagram illustrating an example of a configuration of an electronic apparatus including the imaging device.

FIG. 25 is a block diagram depicting an example of schematic configuration of a vehicle control system.

FIG. 26 is a diagram of assistance in explaining an example of installation positions of an outside-vehicle information detecting section and an imaging section.

FIG. 27 is a view depicting an example of a schematic configuration of an endoscopic surgery system.

FIG. 28 is a block diagram depicting an example of a functional configuration of a camera head and a camera control unit (CCU). Modes for Carrying Out the Invention

Hereinafter, embodiments of the present disclosure will be described in detail with reference to the drawings. It is to be noted that description is given in the following order:
1. Embodiment
2. Modification Examples
3. Application Example
4. Practical Application Examples

### 1. EMBODIMENT

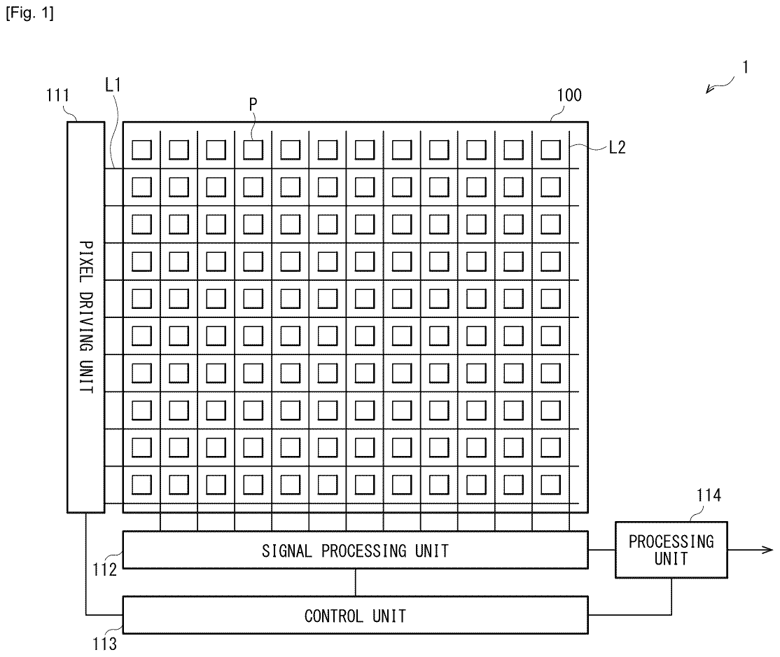

FIG. 1 is a block diagram illustrating an example of a schematic configuration of an imaging device, which is an example of a photodetector according to an embodiment of the present disclosure. The photodetector is a device configured to detect entering light. An imaging device 1, serving as the photodetector, includes a plurality of pixels P, each of which including a photoelectric conversion section (photoelectric converter), and being configured to generate a signal by photoelectric conversion of the entering light. The imaging device 1 (photodetector) is configured to generate a signal by receiving light transmitted through an optical system (not illustrated) including an optical lens.

The imaging device 1 is configured, for example, by using a semiconductor substrate (for example, a silicon substrate) on which the plurality of pixels P is provided. The photoelectric conversion section of each of the pixels P of the imaging device 1 is, for example, a photodiode (PD), and is configured to photoelectrically convert light. The imaging device 1 includes a region (pixel unit 100) as an imaging region, in which the plurality of pixels P is arranged two-dimensionally to form a matrix. The pixel unit 100 is a pixel array in which the plurality of pixels P is arranged, and may also be referred to as a light receiving region.

The imaging device 1 captures entering light (image light) from a subject via the optical system including the optical lens. The imaging device 1 captures an image of the subject formed by the optical lens. The imaging device 1 is configured to generate a pixel signal by photoelectric conversion of the received light. The imaging device 1 is, for example, a COMS (Complementary Metal Oxide Semiconductor) image sensor. The imaging device 1 may be utilized for electronic apparatuses including, for example, digital still cameras, video cameras, and mobile phones.

As illustrated in an example of FIG. 1, the imaging device 1 includes, for example, a pixel driving unit 111, a signal processing unit 112, a control unit 113, and a processing unit 114, etc., in a peripheral region of the pixel unit 100 (pixel array). Moreover, the imaging device 1 is provided with a plurality of control lines L1 and a plurality of signal lines L2.

The control line L1 is a signal line configured to transmit signals for controlling the pixels P, and coupled to the pixel driving unit 111, and to the pixels P of the pixel unit 100. In the example of FIG. 1, with regard to the pixel unit 100, each of the plurality of control lines L1 is wired for a corresponding row of pixels configured by the plurality of pixels P arranged in a horizontal direction (row direction). The control line L1 is configured to transmit a control signal for reading signals from the pixels P.

Each of the plurality of control lines L1 for the corresponding pixel row of the imaging device 1 includes, as an example, a wiring for transmitting signals for controlling a transfer transistor, a wiring for transmitting signals for controlling a selection transistor, and a wiring for transmitting signals for controlling a reset transistor, etc. The control line L1 may also be referred to as a driving line (pixel driving line), which transmits signals for driving the pixels P.

The signal line L2 is a signal line configured to transmit signals from the pixels P, and coupled to the pixels P of the pixel unit 100, and to the signal processing unit 112. For example, one or more of the signal lines L2 are coupled to each of a column of pixels configured by the plurality of pixels P arranged to be in a perpendicular direction (column direction).

The signal line L2 is a vertical signal line, and is configured to transmit signals outputted from the pixels P. With regard to the imaging device 1, a plurality of signal lines L2 may be provided for one pixel column. The imaging device 1 may have a plurality of signal lines L2 for each of the pixel columns.

The pixel driving unit 111 is configured to drive each of the pixels P of the pixel unit 100. The pixel driving unit 111 is a driving circuit, and is configured by a plurality of circuits including, for example, a buffer, a shift register, and an address decoder. The pixel driving unit 111 generates a signal for driving the pixels P, and outputs the signal to each of the pixels P of the pixel unit 100, via the control line L1. The pixel driving unit 111 is controlled by the control unit 113, and controls the pixels P of the pixel unit 100.

The pixel driving unit 111 generates signals for controlling the pixel P, such as signals for controlling the transfer transistor of the pixel P, signals for controlling the selection transistor, or signals for controlling the reset transistor, and supplies the signals to each of the pixel P through the control line L1. The pixel driving unit 111 is configured to control reading of pixel signals from each of the pixels P. The pixel driving unit 111 may be referred to as a pixel control unit that is configured to control each of the pixel P. Note that the pixel driving unit 111 and the control unit 113 may also be collectively referred to as the pixel control unit.

The signal processing unit 112 is configured to execute signal processing of inputted pixel signal. The signal processing unit 112 is a signal processing circuit, and includes, for example, a load circuit unit, an AD (analog-digital) converter, and a horizontal selection switch, etc. Note that the signal processing unit 112 may include an amplification circuit unit, which is configured to amplify signals read from the pixel P via the signal line L2.

The signal outputted from each of the pixel P, which has been selectively scanned by the pixel driving unit 111, is inputted in the signal processing unit 112 via the signal line L2. The signal processing unit 112 is configured to perform signal processing of the pixel P, such as AD conversion or CDS (correlated double sampling). The signal of each of the pixels P, which has been transmitted by the corresponding signal line L2, is processed by the signal processing unit 112 and outputted to the processing unit 114.

The processing unit 114 is configured to execute signal processing for the inputted signal. The processing unit 114 is a signal processing circuit, and is configured, for example, by a circuit which performs various types of signal processing on the pixel signal. The processing unit 114 may include a processor and a memory. The processing unit 114 performs signal processing on the pixel signal inputted from the signal processing unit 112, and outputs the processed pixel signal. The processing unit 114 is configured to perform various types of signal processing, such as noise reduction processing or tone compensation processing.

The control unit 113 is configured to control each part of the imaging device 1. The control unit 113 receives, a clock given from the outside, data for commanding operation modes, etc., and is configured to output data such as internal information of the imaging device 1. The control unit 113 is a control circuit, and includes, for example, a timing generator configured to generate various timing signals.

The control unit 113 performs driving control of the pixel driving unit 111, the signal processing unit 112, etc., on the basis of various timing signals (pulse signals, clock signals, etc.) generated by the timing generator. Note that the control unit 113 and the processing unit 114 may be configured integrally.

The pixel driving unit 111, the signal processing unit 112, the control unit 113, and the processing unit 114 may be provided on a single semiconductor substrate, or may be provided separately on a plurality of semiconductor substrates. The imaging device 1 may be in a structure configured by stacking a plurality of substrates (stacked structure).

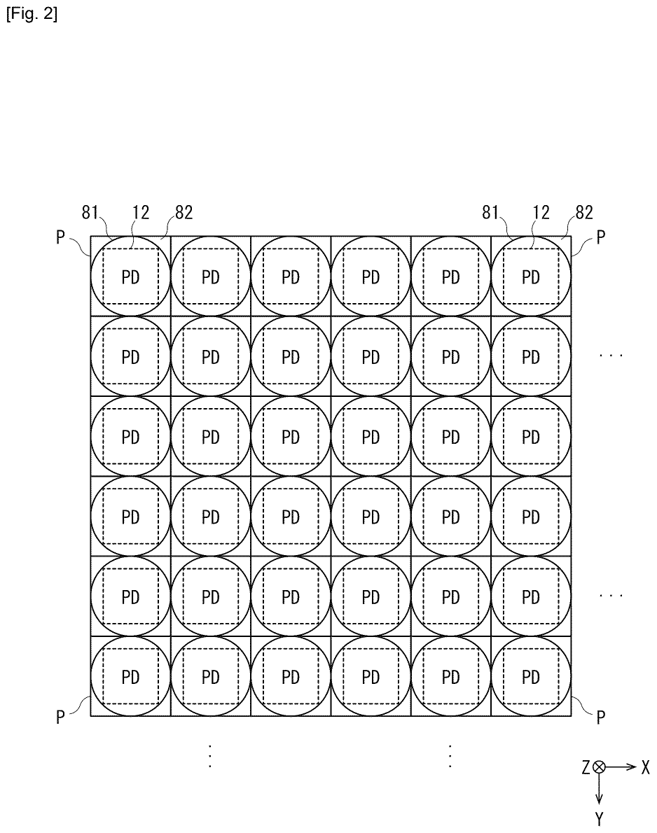

FIG. 2 is a diagram illustrating an example of arrangement of pixels of the imaging device according to the embodiment. The pixel P of the imaging device 1 includes a photoelectric conversion section 12 and a lens 81. Note that, as illustrated in FIG. 2, a direction of light entering from a subject shall be referred to as a Z-axis direction, a right-left direction as seen on a drawing paper perpendicular to the Z-axis direction shall be referred to as an X-axis direction, and a top-bottom direction as seen on the drawing paper perpendicular to the Z-axis direction and also to the X-axis direction shall be referred to as a Y-axis direction. With regard to drawings hereinafter, the directions may be sometimes expressed by using the directions of arrows of FIG. 2 as the reference.

The lens 81 is an optical member also referred to as an on-chip lens. The lens 81 is provided above the photoelectric conversion section 12, for example, per pixel P, or per multiple pixels P. The light from the subject enters the lens 81 via an optical system such as an image capturing lens. The photoelectric conversion section 12 performs photoelectric conversion on the light entering via the lens 81.

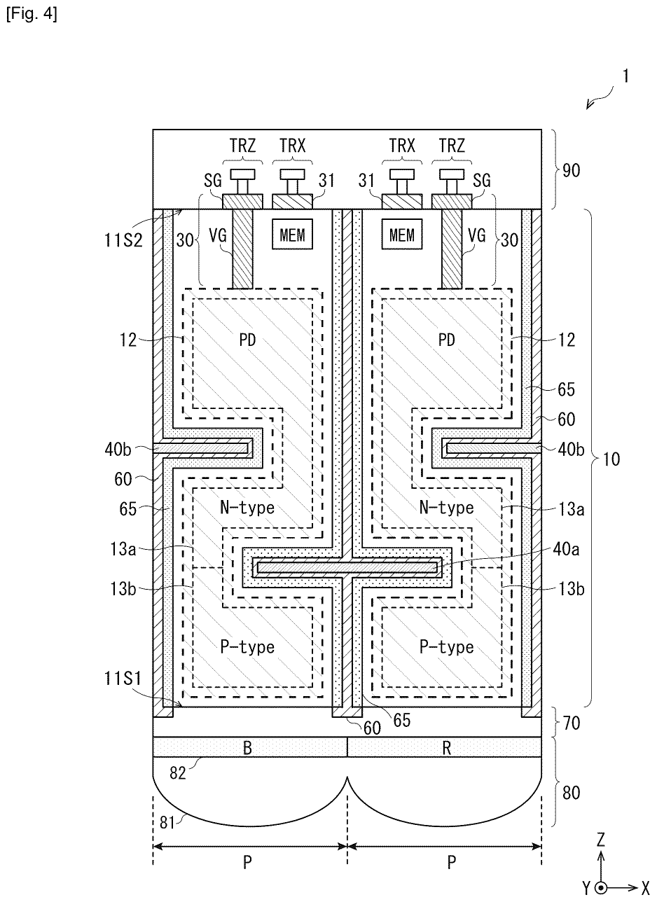

Moreover, the pixel P may include a filter 82 (see also FIG. 4 described below). The filter 82 is configured to selectively transmit light having a specific wavelength range among the entering light. The filter 82 is, for example, an RGB color filter, an infrared light transmitting filter, etc.

A plurality of pixels (R pixels) provided with the filter 82 transmitting red (R) light, a plurality of pixels (G pixels) provided with the filter 82 transmitting green (G) light, and a plurality of pixels (B pixels) provided with the filter 82 transmitting blue (B) light, are included in the plurality of pixels P provided in the pixel unit 100 of the imaging device 1. The plurality of R pixels, the plurality of G pixels, and the plurality of B pixels, are repeatedly arranged in the pixel unit 100. The R pixels, the G pixels, and the B pixels are arranged, for example, according to the Bayer arrangement.

As an example, the R pixels, the G pixels, and the B pixels may be arranged in units of 2-pixel by 2-pixel each. For example, four R pixels adjacent to each other, and four G pixels adjacent to each other, and four B pixels adjacent to each other are repeatedly arranged in the pixel unit 100. Thus, it may also be understood that the R pixels, the G pixels, and the B pixels are arranged cyclically in units of 2-row by 2-column each.

The R pixel, the G pixel, and the B pixel generate, respectively, a pixel signal of R component, a pixel signal of G component, and a pixel signal of B component. It is possible for the imaging device 1 to acquire RGB pixel signals. Note that the arrangement of pixels is not limited to the above example, and may be set as desired.

The filter 82 provided in the pixel P in the pixel unit 100 is not limited to a color filter according to the primary color system (RGB), and a color filter according to the complementary color system, such as Cy (cyan), Mg (magenta), or Ye (yellow), may also be used. Furthermore, a filter corresponding to W (white), which is a filter transmitting an entire wavelength range of the entering light, may also be disposed.

Moreover, depending on the necessity, the imaging device 1 may omit the filter 82. For example, with regard to the pixel P that receives white (W) light and performs photoelectric conversion, it is not necessary to provide the filter 82. Moreover, it is possible not to provide the filters 82 for a part of all of the pixels P of the imaging device 1.

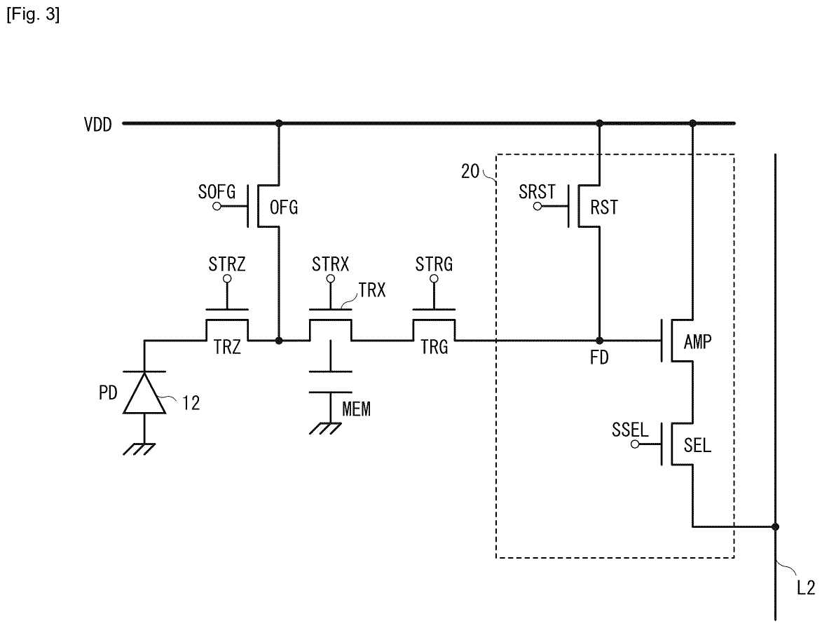

FIG. 3 is a diagram explaining an example of a circuit configuration of the pixel of the imaging device according to the embodiment. The pixel P of the imaging device 1 includes the photoelectric conversion section 12 (photoelectric converter), a transistor TRZ, a transistor TRX, a transistor TRG, a transistor OFG, and a reading circuit 20. The photoelectric conversion section 12 is configured to receive light and generate signals.

The photoelectric conversion section 12 is a light receiving section (light receiving element) configured to generate electric charge by photoelectric conversion. In the example of FIG. 3, the photoelectric conversion section 12 is a photodiode (PD), and converts the entering light into the electric charge. The photoelectric conversion section 12 performs photoelectric conversion and generates the electric charge corresponding to an amount of received light.

The transistor TRZ is configured to transfer the electric charge, which has been photoelectrically converted by the photoelectric conversion section 12, to the transistor TRX and a capacitor MEM. The transistor TRZ is controlled by a signal STRZ, and electrically couples or decouples the photoelectric conversion section 12 and the transistor TRX to or from each other. The transistor TRZ is a transfer transistor, and is configured to transfer the electric charge, which has been photoelectrically converted by the photoelectric conversion section 12 and accumulated, to the transistor TRX and the capacitor MEM.

The transistor TRX is configured to control potential of the capacitor MEM. The transistor TRX is controlled by a signal STRX, and is configured to control (adjust) the potential of the capacitor MEM. The transistor TRX is configured to adjust (change), for example, a height of a potential barrier formed between the transistor TRZ and the capacitor MEM.

For example, in a case where the transistor TRX is turned ON, the potential of the capacitor MEM becomes deeper, and in a case where the transistor TRX is turned OFF, the potential of the capacitor MEM becomes shallower. The transistor TRZ transfers the electric charge, which has been photoelectrically converted by the photoelectric conversion section 12, to the capacitor MEM via the transistor TRX.

The capacitor MEM is an accumulating section (or a memory section), configured to accumulate the transferred electric charge. The capacitor MEM is configured, for example, by an MOS capacitor, an MIM (metal-insulator-metal) capacitor, etc. The capacitor MEM is configured to accumulate the electric charge which has been photoelectrically converted by the photoelectric conversion section 12. The capacitor MEM may also be referred to as a holding section configured to hold the transferred electric charge.

The transistor TRG is configured to transfer the electric charge, which has been accumulated in the capacitor MEM, to a floating diffusion FD of the reading circuit 20. The transistor TRG is controlled by a signal STRG, and electrically couples or decouples the transistor TRX and the floating diffusion FD to or from each other.

The transistor TRG is a transfer transistor, and is configured to transfer the electric charge, which has been accumulated in the capacitor MEM, to the floating diffusion FD. For example, the electric charge, which has been accumulated in the capacitor MEM, is transferred to the floating diffusion FD, via the transistor TRX and the transistor TRG.

The transistor OFG is configured to reset the electric charge of the photoelectric conversion section 12. In the example as illustrated in FIG. 3, the transistor OFG is electrically coupled to a power supply line, through which an electric power voltage VDD is given, and is configured to reset the photoelectric conversion section 12. The transistor OFG is configured to discharge the electric charge, which has been accumulated in the photoelectric conversion section 12, and to reset a voltage of the photoelectric conversion section 12, via the transistor TRZ. The transistor OFG is a reset transistor.

The reading circuit 20 is configured to output signals based on the photoelectrically converted electric charge. As an example, the reading circuit 20 includes, the floating diffusion FD, a transistor AMP, a transistor SEL, and a transistor RST. Note that the reading circuit 20 may also include the transistor TRZ, the transistor TRX, the transistor TRG, the transistor OFG, etc. described above.

With regard to the imaging device 1, the reading circuit 20 may be provided, for example, per pixel P or per multiple pixels P. The imaging device 1 may also be in a configuration that, for example, the plurality of pixels P shares a single reading circuit 20. The imaging device 1 may also be in a configuration that, for example, the plurality of pixels P adjacent to each other shares the transistor AMP, the transistor RST, etc. of the reading circuit 20.

The floating diffusion FD is an accumulating unit, and is configured to accumulate the transferred electric charge. The floating diffusion FD is configured to accumulate the electric charge which has been photoelectrically converted by the photoelectric conversion section 12. The floating diffusion FD may be referred to as a holding section configured to hold the transferred electric charge. The floating diffusion FD accumulates the transferred electric charge, and converts it into a voltage corresponding to a capacity of the floating diffusion FD.

The transistor AMP is configured to generate and output signals based on the electric charge which has been accumulated in the floating diffusion FD. As illustrated in FIG. 3, the gate of the transistor AMP is electrically coupled to the floating diffusion FD, and receives a voltage which has been converted by the floating diffusion FD.

The drain of the transistor AMP is coupled to a power supply line through which the electric power voltage VDD is supplied, and the source of the transistor AMP is coupled to the signal line L2 via the transistor SEL. The transistor AMP is an amplification transistor, and is configured to generate signals based on the electric charge accumulated in the floating diffusion FD, i.e. the signals based on the voltage of the floating diffusion FD, and to output the signals to the signal line L2.

The transistor SEL is configured to control the pixel signal output. The transistor SEL is controlled by a signal SSEL, and is configured to output signals from the transistor AMP to the signal line L2. The transistor SEL is a selection transistor, and is configured to control an output timing of the pixel signal. Note that the transistor SEL may be provided between a power supply line, through which the electric power voltage VDD is given, and the transistor AMP. Moreover, depending on the necessity, the transistor SEL may be omitted.

The transistor RST is configured to reset a voltage of the floating diffusion FD. In the example as illustrated in FIG. 3, the transistor RST is electrically coupled to a power supply line, through which the electric power voltage VDD is given, and is configured to reset the electric charge of the pixel P.

The transistor RST is controlled by a signal SRST, and is configured to reset the electric charge accumulated in the floating diffusion FD, and to reset the voltage of the floating diffusion FD. The transistor RST is a reset transistor.

The transistor TRZ, the transistor TRX, the transistor TRG, the transistor OFG, the transistor AMP, the transistor SEL, and the transistor RST described above are all MOS transistors (MOSFETs) each of which has the gate, source, and drain terminals.

In the example as illustrated in FIG. 3, the transistor TRZ, the transistor TRX, the transistor TRG, the transistor OFG, the transistor AMP, the transistor SEL, and the transistor RST are all NMOS transistors. Note that the transistors of the pixel P may be PMOS transistors.

Note that the configuration of the reading circuit 20 may be modified appropriately, and is not limited to the above example. For example, the reading circuit 20 may be configured to vary conversion efficiency (gain) when converting the electric charge to the voltage. For example, the reading circuit 20 may include a switching transistor used for setting of the conversion efficiency. The switching transistor is provided, as an example, between the floating diffusion FD and the transistor RST.

The switching transistor may be coupled to the transistor RST in parallel. For example, the switching transistor may be configured to electrically couple the floating diffusion FD and a capacitance for switching the gain to each other.

With regard to the reading circuit 20, when the switching transistor turns ON, capacity added to the floating diffusion FD of the pixel P becomes larger, and the conversion efficiency is switched. The switching transistor is configured to switch capacity coupled to the gate of the transistor AMP, and to vary the conversion efficiency.

The pixel driving unit 111 (see FIG. 1) supplies, via the control lines L1 described above, the control signals to the gates of the transistors TRZ, TRX, TRG, OFG, AMP, SEL, and RST of each of the pixels P, and causes the transistors to be turned ON (conductive state) or OFF (non-conductive state).

The plurality of control lines L1 of the imaging device 1 includes a wiring for transmitting the signal STRZ for controlling the transistor TRZ, a wiring for transmitting the signal STRX for controlling the transistor TRX, a wiring for transmitting the signal STRG for controlling the transistor TRG, a wiring for transmitting a signal SOFG for controlling the transistor OFG, etc. Moreover, the plurality of control lines L1 of the imaging device 1 includes a wiring for transmitting the signal SSEL for controlling the transistor SEL, a wiring for transmitting the signal SRST for controlling the transistor RST, etc.

The pixel driving unit 111 controls ON/OFF of the transistor TRZ, the transistor TRX, the transistor TRG, the transistor OFG, the transistor SEL, the transistor RST, etc. The pixel driving unit 111 causes each of the pixels P to output the pixel signal to the signal line L2, by controlling each of the pixels P. The pixel driving unit 111 is configured to control reading of the pixel signal of each of the pixels P to the signal line L2.

It is possible for each of the pixels P of the imaging device 1 to temporarily accumulate the electric charge, which has been photoelectrically converted by the photoelectric conversion section 12, in the capacitor MEM of each of the pixels P. Therefore, it is possible for the imaging device 1 to achieve a global shutter. The pixel P is a pixel configured to be operated in a global shutter mode, and may be referred to as a global shutter pixel. In a case of the global shutter, the pixel driving unit 111 may, for example, collectively reset the electric charges of the photoelectric conversion sections 12 of the pixels P, by controlling the transistor OFG of each of the pixels P.

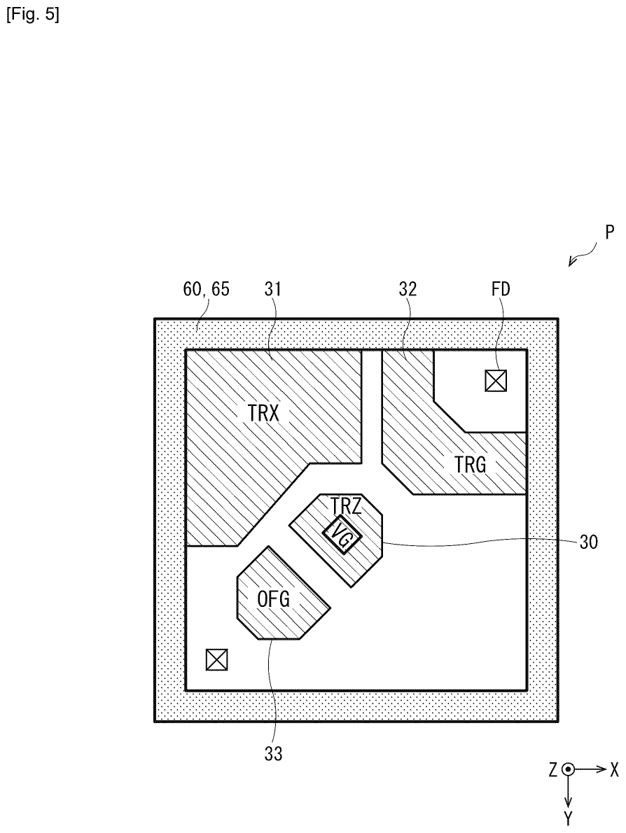

FIG. 4 is a diagram illustrating an example of a cross-sectional configuration of the imaging device according to the embodiment. Moreover, FIG. 5 is a diagram illustrating an example of a plan configuration of the pixel of the imaging device according to the embodiment. The imaging device 1 is, for example, as illustrated in FIG. 4, configured by a light guiding unit 80, an insulation layer 70, a semiconductor layer 10, and a multi-layer wiring layer 90 that are stacked in the Z-axis direction.

As illustrated in FIG. 4, the semiconductor layer 10 includes a first surface 11S1 and a second surface 11S2 opposed to each other. The second surface 11S2 is a surface on an opposite side to the first surface 11S1. The semiconductor layer 10 is configured by a semiconductor substrate, for example, by an Si (silicon) substrate. The first surface 11S1 of the semiconductor layer 10 is a light receiving surface (light entering surface). The second surface 11S2 of the semiconductor layer 10 is an element forming surface, on which elements, such as transistors, etc., are formed.

The second surface 11S2 of the semiconductor layer 10 is provided with gate electrodes, gate oxide films (not illustrated), etc. FIG. 4 illustrates the transistor TRZ, the transistor TRX, and the capacitor MEM. A gate electrode 30 of the transistor TRZ is formed, via the gate oxide film (not illustrated), on the side of the second surface 11S2 of the semiconductor layer 10.

The gate electrode 30 includes, for example, polysilicon (Poly-Si). The gate electrode 30 may include a metal material, a metal compound, etc. The gate electrode 30 may include, for example, titanium nitride (TiN), tantanium nitride (TaN), etc.

Moreover, a gate electrode 31 of the transistor TRX, a gate electrode 32 of the transistor TRG, and a gate electrode 33 of the transistor OFG illustrated in FIG. 4 and FIG. 5 may also include polysilicon, a metal material, a metal compound, etc. Moreover, the gate electrodes 30 to 33 may also include a material including at least any one of titanium, nickel, zirconium, tantalum, tungsten, aluminum, hafnium, etc.

In the example as illustrated in FIG. 4, the insulation layer 70 and the light guiding unit 80 are provided on the side of the first surface 11S1 of the semiconductor layer 10. The multi-layer wiring layer 90 is provided on the side of the second surface 11S2 of the semiconductor layer 10. The light guiding unit 80 and the like are provided on a side of entering light from an optical system, and the multi-layer wiring layer 90 is provided on a side opposite to the light entering side. The imaging device 1 is what is called a backside-illuminated imaging device.

In the semiconductor layer 1, the plurality of photoelectric conversion sections 12 (photoelectric converters) is provided along the first surface 11S1 and the second surface 11S2 of the semiconductor layer 10. For example, the plurality of photoelectric conversion sections 12 is formed by embedding. As schematically illustrated in FIG. 4, the photoelectric conversion section 12 is configured by including an N-type semiconductor region 13a and a P-type semiconductor region 13b.

Moreover, the semiconductor layer 10 is provided with the plurality of capacitors MEM. The capacitor MEM is provided to be stacked with the photoelectric conversion section 12. The capacitor MEM may be arranged, for example, to be embedded in the semiconductor layer 10. In the example as illustrated in FIG. 4, the capacitor MEM is formed in the semiconductor layer 10, positioned above the photoelectric conversion section 12.

The imaging device 1 has a configuration in which the photoelectric conversion section 12 and the capacitor MEM are stacked on each other. It may be understood that the photoelectric conversion section 12 and the capacitor MEM are stacked vertically. Note that the semiconductor layer 10 may be an SOI (silicon on insulator) substrate, an SiGe (silicon germanium) substrate, an SiC (silicon carbide) substrate, or the like, and may include a Group III-V compound semiconductor material or the like.

The multi-layer wiring layer 90 includes, for example, a conductive film and an insulation film, and includes a plurality of wirings, vias (VIAs), etc. The multi-layer wiring layer 90 includes, for example, wirings of two or more layers. The multi-layer wiring layer 90 has a configuration in which a plurality of wirings are stacked on each other with the insulation film interposed therebetween. The insulation film of the multi-layer wiring layer 90 may also be referred to as an interlayer insulation film (interlayer insulation layer).

The wiring of the multi-layer wiring layer 90 is formed, for example, by using a metal material such as aluminum (Al), copper (Cu), or tungsten (W). The wiring of the multi-layer wiring layer 90 may include polysilicon (Poly-Si) or other conductive materials. The interlayer insulation film is formed by using, for example, silicon oxide (SiO), silicon nitride (NiO), silicon oxynitride (SiON), etc.

The semiconductor layer 10 and the multi-layer wiring layer 90 are provided, for example, with the transistors (the transistor TRZ, the transistor TRX, the transistor TRG, the transistor OFG, etc.) of the pixel P described above. Note that the reading circuit 20, the pixel driving unit 111, the signal processing unit 112, the control unit 113, the processing unit 114, etc., described above, may be provided, on an substrate (semiconductor substrate) other than the semiconductor layer 10, or on the semiconductor layer 10 and the multi-layer wiring layer 90.

The light guiding unit 80 is stacked on the semiconductor layer 10 and the insulation layer 70 in the thickness direction perpendicular to the first surface 11S1 of the semiconductor layer 10. The light guiding unit 80 includes the lens 81 and the filter 82, and guides the entering light to the side of the semiconductor layer 10. The photoelectric conversion section 12 performs photoelectric conversion of the light entering via the lens 81 and the filter 82.

The insulation layer 70 is provided between the light guiding unit 80 and the semiconductor layer 10. The insulation layer is formed, for example, by using an insulation film such as an oxide film, a nitride film, or an oxynitride film. The insulation layer 70 may include silicon oxide (SiO), silicon nitride (SiN), silicon oxynitride (SiON), or other insulation materials. The insulation layer 70 may also be referred to as a flattening layer (flattening film).

Moreover, as illustrated in the examples of FIG. 4 and FIG. 5, the imaging device 1 is provided with a separation part 60. The separation part 60 is formed between the plurality of photoelectric conversion sections 12 adjacent each other in the semiconductor layer 10, and separates the photoelectric conversion sections 12. The separation part 60 is configured by using a trench (groove) provided on boundaries of the pixels P adjacent to each other. The separation part 60 has, for example, a DTI (deep trench isolation) structure.

In the example as illustrated in FIG. 4, the separation part 60 is provided to penetrate through the semiconductor layer 10. The separation part 60 is provided, for example, to surround each of the photoelectric conversion sections 12 in the semiconductor layer 10. As illustrated in FIG. 5, the separation part 60 is provided, in a plan view, to surround the plurality of elements (the transistor TRZ, the transistor TRX, the transistor TRG, the transistor OFG, etc.) of the pixel P.

As an example, an insulation film such as an oxide film (for example, a silicon oxide film) or a nitride film (for example, a silicon nitride film) is provided in the trench of the separation part 60. Note that polysilicon, a metal material, etc. may be embedded in the trench of the separation part 60.

Because the separation part 60 is provided, leaking of the electric charge, which has been photoelectrically converted by the photoelectric conversion section 12 of the pixel P, to the pixels P around it is prevented. Moreover, it is possible to prevent leaking of light to the pixels P around it. Note that, as the separation part 60, a separation part forming a potential barrier may be provided between the photoelectric conversion sections 12 adjacent to each other, to electrically separate the photoelectric conversion sections 12 adjacent to each other.

As illustrated in FIG. 4, a semiconductor region 65 is provided on a side wall of the separation part 60. The semiconductor region 65 is a predetermined conductive-type of semiconductor region, and a semiconductor layer formed by using impurities. The semiconductor region 65 is, for example, a p-type semiconductor region, and is a doping layer doped with p-type impurities.

The semiconductor region 65 is provided on the side surface (side part) of the separation part 60, for example by ion implantation or solid phase diffusion. The semiconductor region 65 is a pinning film (pinning layer), and may be formed to cover the side wall of the separation part 60. Because the semiconductor region 65 is provided, generation of dark current is suppressed.

Moreover, as illustrated in FIG. 4, the imaging device 1 includes a light shielding part 40. The light shielding part (in FIG. 4, a light shielding part 40a and a light shielding part 40b) is a light shielding member including a member to shield the light, and is provided in the semiconductor layer 10. The light shielding part 40a and the light shielding part 40b are both provided in regions in which the photoelectric conversion section 12 is located, and may be understood as being arranged by replacing parts of the photoelectric conversion section 12. Note that, in the example illustrated in FIG. 4, the light shielding part 40 is not provided between the photoelectric conversion section 12 and the capacitor MEM.

Both the light shielding part 40a and the light shielding part 40b extend in a direction perpendicular to the thickness direction of the semiconductor layer 10, that is, in the X-axis direction (and in the Y-axis direction). The light shielding part 40a and the light shielding part 40b may be disposed to allow a part of the photoelectric conversion section 12 to be interposed therebetween. In the example illustrated in FIG. 4, the light shielding part 40a and the light shielding part 40b are arranged to overlap each other.

Both the light shielding part 40a and the light shielding part 40b include a light-shielding metal material (aluminum (Al), tungsten (W), copper (Cu), etc.). The light shielding part 40a and the light shielding part 40b may include a light-absorbing material.

The light shielding part 40a and the light shielding part 40b may be formed, for example, by performing wet etching on the trench of the separation part 60, with the use of face orientation dependence. The light shielding part 40a and the light shielding part 40b may be provided to be embedded in the lateral directions (the X-axis direction and the Y-axis direction) from the trench of the separation part 60.

Because the light shielding part 40a and the light shielding part 40b are provided, it is possible for the imaging device 1 to suppress entry of unnecessary light into the capacitor MEM. It is also possible to suppress mixing of noise into the pixel signal, and consequently, to improve the PLS (parasitic light sensitivity) characteristics.

With regard to the imaging device 1, the gate electrode 30 of the transistor TRZ is provided to reach the photoelectric conversion section 12 in the semiconductor layer 10. At least a part of the gate electrode 30 may be disposed to be embedded in the semiconductor layer 10. The gate electrode 30 includes a first part VG, which is provided to reach the photoelectric conversion section 12 in the semiconductor layer 10, and a second part SG, which is provided on the side of the second surface 11S2 of the semiconductor layer 10.

The first part VG, serving as a part of the gate electrode 30 of the transistor TRZ, is formed into the semiconductor layer 10 to be located, for example, in the inside of the semiconductor layer 10, as illustrated in the example of FIG. 4. The transistor TRZ is in a vertical gate structure.

The first part VG of the gate electrode 30 of the transistor TRZ is provided, for example, from the side of the second surface 11S2 of the semiconductor layer 10, to the photoelectric conversion section 12, as illustrated in the example of FIG. 4. Note that the gate insulation film of the transistor TRZ is formed along the first part VG of the gate electrode 30, in the inside of the semiconductor layer 10.

When the transistor TRZ is turned ON, the electric charge, which has been photoelectrically converted by the photoelectric conversion section 12, is transferred to the capacitor MEM via a side surface (side part) of the gate insulation film of the first part VG. Thus, the transistor TRZ is configured to transfer the electric charge, which has been photoelectrically converted by the photoelectric conversion section 12, to the capacitor MEM provided for that photoelectric conversion section 12.

With regard to the imaging device 1, as illustrated in the examples of FIG. 4 and FIG. 5, the gate electrode 30 of the transistor TRZ is provided in a region away from the separation part 60. The gate electrode 30 of the transistor TRZ is disposed at a position away from the separation part 60, which has been provided in all directions, for example, at a center part of the pixel P. With regard to the pixel P, the transistor TRZ is provided, for example, to be adjacent to the transistor TRG.

In the example illustrated in FIG. 5, the gate electrode 30 of the transistor TRZ is provided, in a plan view, to be adjacent to the gate electrode 32 of the transistor TRG. The distance between the gate electrode 30 and the separation part 60 is larger than the distance between the gate electrode 32 and the separation part 60. Moreover, in the example as illustrated in FIG. 5, the transistor TRG and the transistor OFG are disposed to allow the transistor TRZ to be interposed therebetween.

At least a part of the transistor TRZ may be provided at a center of the pixel P, in a plan view. At least a part of the gate electrode 30 of the transistor TRZ may be provided at the center of the pixel P. Moreover, at least a part of the first part VG of the gate electrode 30 may be disposed at the center of the pixel P.

In a case where the transistor TRZ is located to be close to the separation part 60 and the semiconductor region 65, it is likely that a strong electric field will be generated between the transistor TRZ and the semiconductor region 65. In a case where the transistor TRZ is turned ON, the strong electric field may be generated between the first part VG of the gate electrode 30 of the transistor TRZ and the semiconductor region 65 (for example, the p-type of semiconductor region), and the pixel signal may be mixed with noise. In particular, in a case where the highly concentrated p-type of semiconductor region 65 exists on the side wall of the separation part 60, it is likely that the strong electric field will be generated, and for example, white spots (white scratches) will appear in the image. Moreover, in a case of a fine pixel, when the strong electric field is generated, there is a tendency for the pixel signal quality and image quality to deteriorate.

Thus, according to the present embodiment, as described above, the gate electrode 30 of the transistor TRZ is provided in a region away from the separation part 60. As compared with the case where the transistor TRZ and the separation part 60 are provided to be close to each other, it is possible to mitigate the electric field generated between the gate electrode 30 of the transistor TRZ and the separation part 60, and also to suppress mixing of noise into the pixel signal. It is possible to suppress the appearance of white spots, etc., in the image.

Furthermore, in the case of the fine pixel, by disposing the transistor TRZ as illustrated in the example of FIG. 5, it is also possible to mitigate the electric field between the gate electrode 30 of the transistor TRZ and the semiconductor region 65. Thus, it is possible to suppress deterioration in the pixel signal quality, and also to suppress deterioration in the image quality.

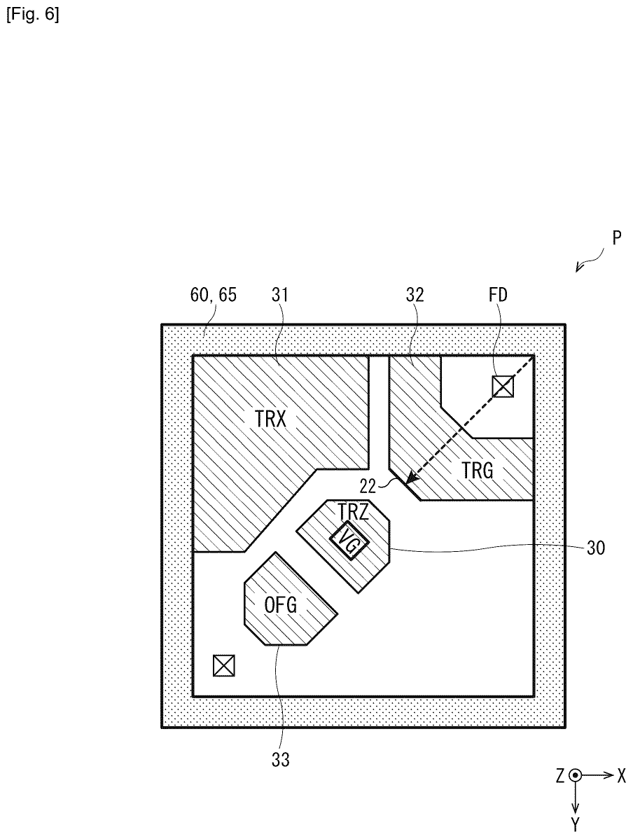

FIG. 6 to FIG. 9 are diagrams each explaining an example of a configuration of the pixel of the imaging device according to the embodiment. The transistor TRZ is provided, for example, to be adjacent to a side (surface) of the transistor TRG. The gate electrode 30 may be provided, for example, as illustrated by an arrow in FIG. 6, to be adjacent to a side 22 that is the farthest side from the separation part 60 among the plurality of sides of the gate electrode 32 of the transistor TRG.

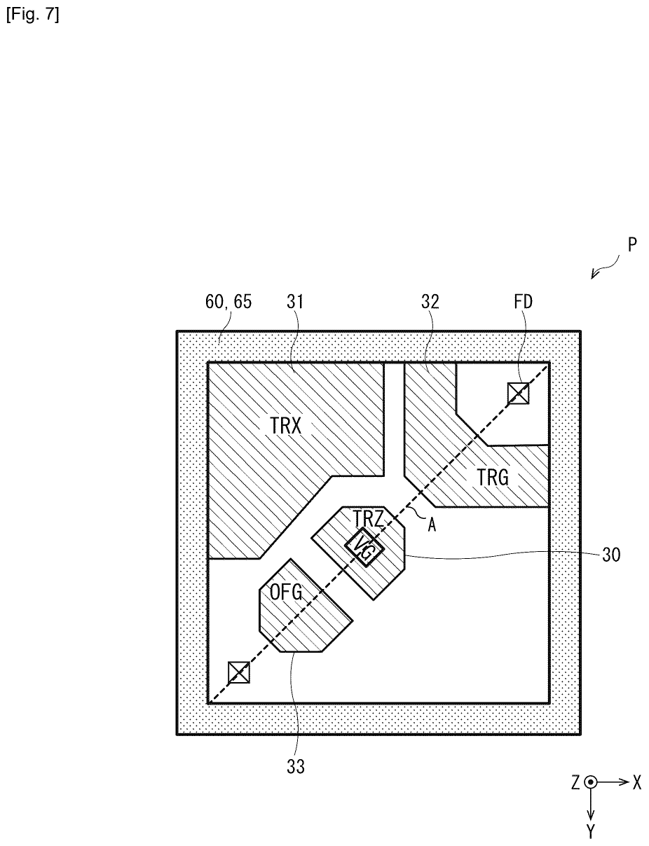

In FIG. 7, a broken line A indicates a diagonal line of the pixel P. At least a part of the transistor TRZ may be provided at a position on the diagonal line of the pixel P. At least a part of the gate electrode 30 of the transistor TRZ may be provided on the diagonal line of the pixel P. As illustrated in an example of FIG. 7, the transistor TRZ may be so disposed that the first part VG of the gate electrode 30 overlaps the diagonal line indicated by the broken line A.

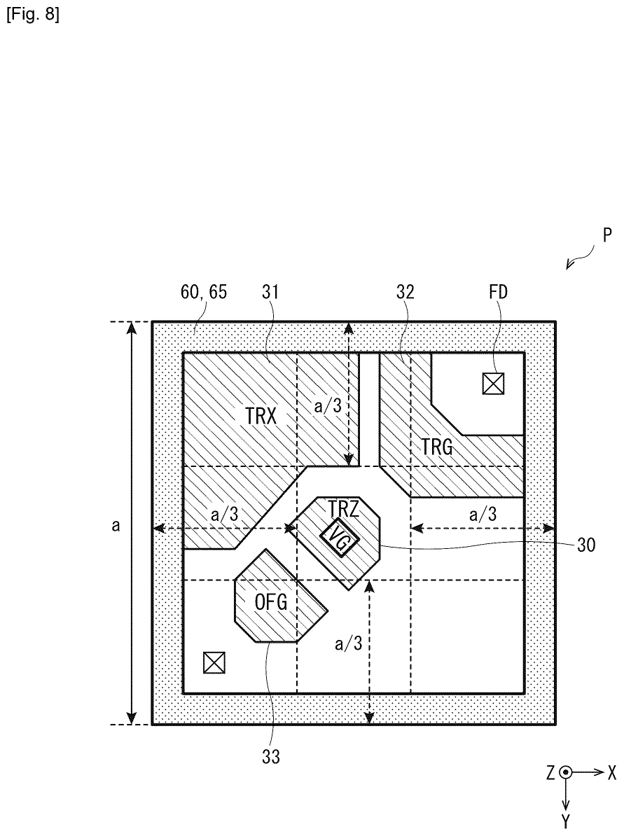

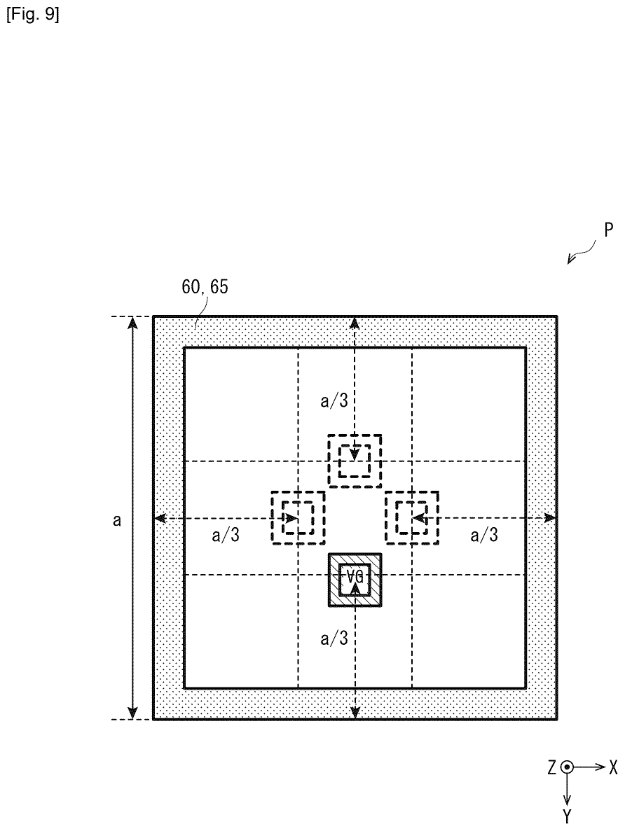

As illustrated in FIG. 8, where the width of the pixel P is defined as “a”, the distance between the center of the first part VG of the gate electrode 30 and the separation part 60 may be greater than or equal to one-third of the width a of the pixel P (=a/3). In an example illustrated in FIG. 8, the distance between the center of the first part VG and an edge of the separation part 60 is greater than or equal to a/3. Note that the location of the first part VG of the gate electrode 30 is not limited to the example illustrated in FIG. 8, and may be modified appropriately, as in an example schematically illustrated in FIG. 9.

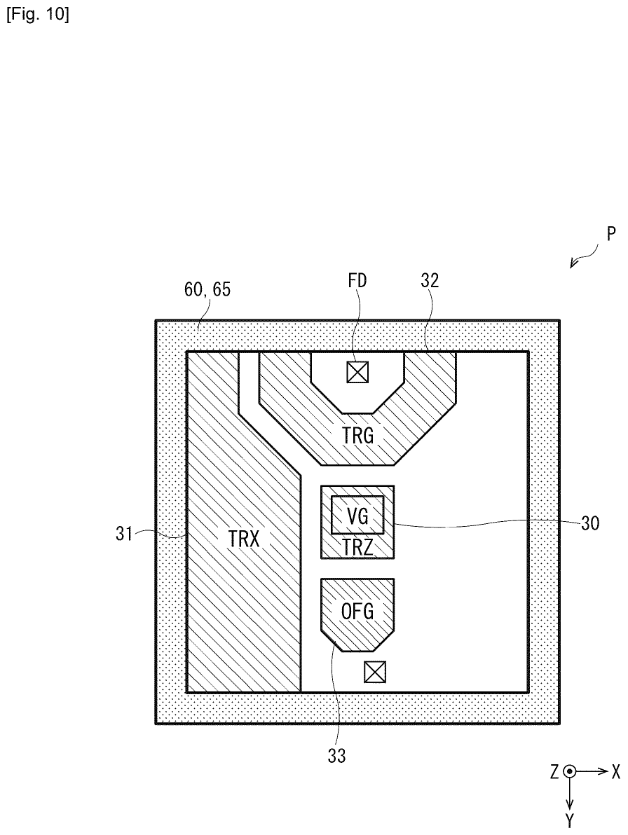

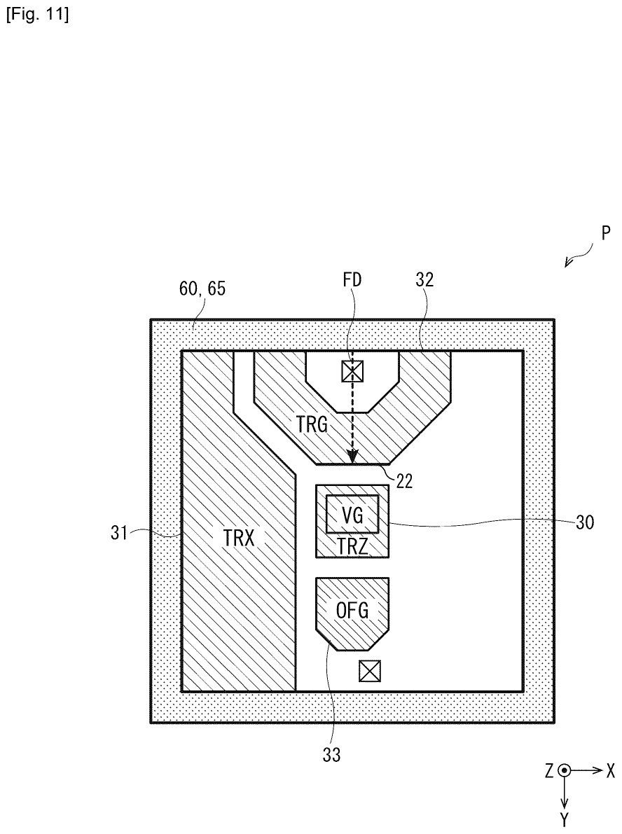

FIG. 10 to FIG. 13A and FIG. 13B are diagrams each explaining another example of the configuration of the pixel of the imaging device according to the embodiment. The pixel P of the imaging device 1 may be configured as illustrated in FIG. 10. The transistor TRZ may be provided, for example, to be adjacent to the side (surface) of the transistor TRG. The gate electrode 30 may be provided, as illustrated by an arrow in FIG. 11, to be adjacent to the side 22 that is the farthest side from the separation part 60 among the plurality of sides of the gate electrode 32 of the transistor TRG.

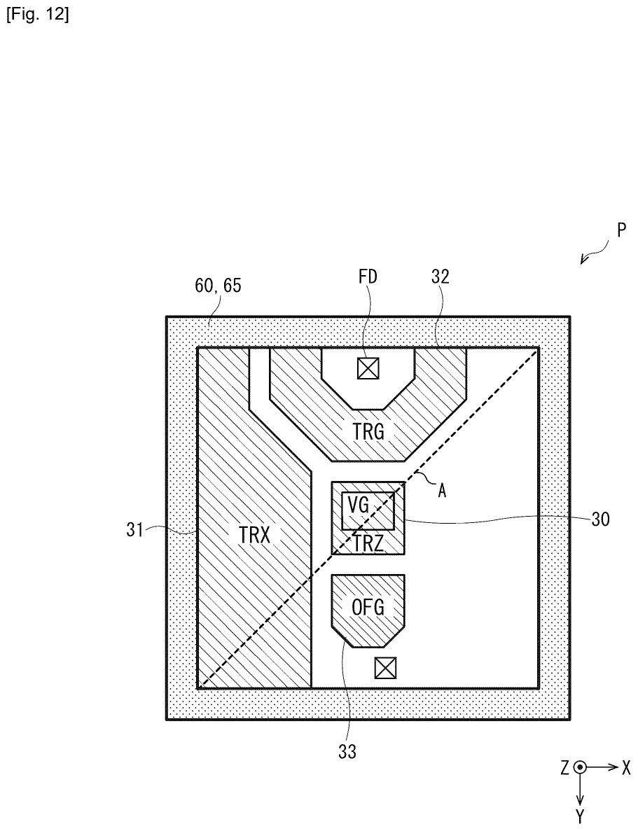

In FIG. 12, at least a part of the transistor TRZ may be provided at a position on the diagonal line of the pixel P. At least a part of the gate electrode 30 of the transistor TRZ may be provided on the diagonal line of the pixel P. The transistor TRZ may be so disposed that the first part VG of the gate electrode 30 overlaps the diagonal line of the pixel P.

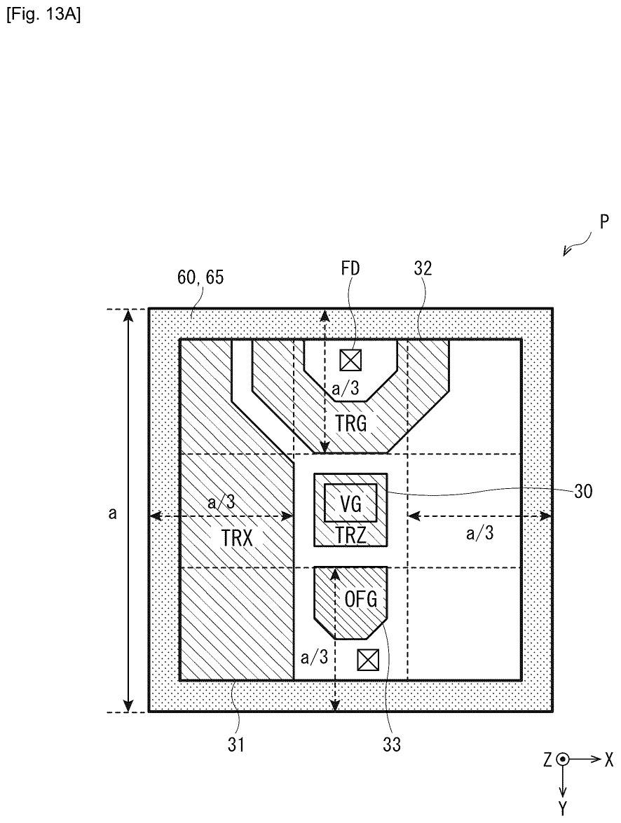

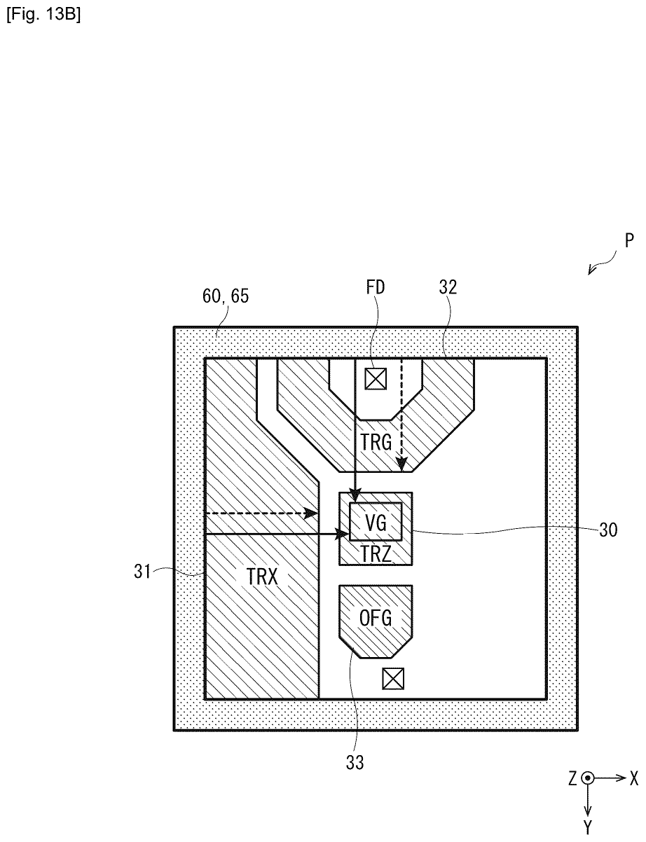

As illustrated in FIG. 13A, where the width of the pixel P is defined as “a”, the distance between the center of the first part VG of the gate electrode 30 and the separation part 60 may be greater than or equal to one-third of the width a of the pixel P (=a/3). In an example illustrated in FIG. 13A, the distance between the center of the first part VG and an edge of the separation part 60 is greater than or equal to a/3.

Note that, as illustrated by arrows in FIG. 13B, a minimum distance from a part of the separation part 60 close to the transistor TRG to the first part VG of the gate electrode 30 may be longer than a maximum distance from the same part of the separation part 60 to the side of the gate electrode 32 of the transistor TRG. Moreover, a minimum distance from a part of the separation part 60 close to the transistor TRX to the first part VG of the gate electrode 30 may be longer than a maximum distance from the same part of the separation part 60 to the gate electrode 31 of the transistor TRX.

### Working and Effects

A photodetector according to the present embodiment includes a plurality of pixels and a separation part (the separation part 60). The plurality of pixels includes a first pixel including a photoelectric converter (the photoelectric conversion section 12) provided in a semiconductor layer (the semiconductor layer 10). The separation part is provided between the pixels adjacent to each other in the semiconductor layer. The first pixel includes a first transistor (the transistor TRZ) and a capacitor (the capacitor MEM). The first transistor includes a first gate electrode (the gate electrode 30), and is configured to transfer electric charge photoelectrically converted by the photoelectric converter. The first gate electrode is provided to reach the photoelectric converter in the semiconductor layer. The capacitor is provided to be stacked on the photoelectric converter, and is configured to accumulate the electric charge photoelectrically converted by the photoelectric converter. The first gate electrode is provided in a region away from the separation part in the semiconductor layer.

In the photodetector (the imaging device 1) according to the present embodiment, the gate electrode 30 of the transistor TRZ is provided in the region away from the separation part 60 in the semiconductor layer 10. Accordingly, it is possible for the imaging device 1 to mitigate the electric field generated between the gate electrode 30 and the separation part 60, and to suppress deterioration in the pixel signal quality. It is possible to achieve the photodetector configured to suppress deterioration in the signal quality.

Next, modification examples of the present disclosure will be explained. Hereinafter, the same reference signs will be allotted for the same structural elements as the above embodiment, and the explanation thereof will be omitted as appropriate.

### 2. MODIFICATION EXAMPLES

### 2-1. Modification Example 1

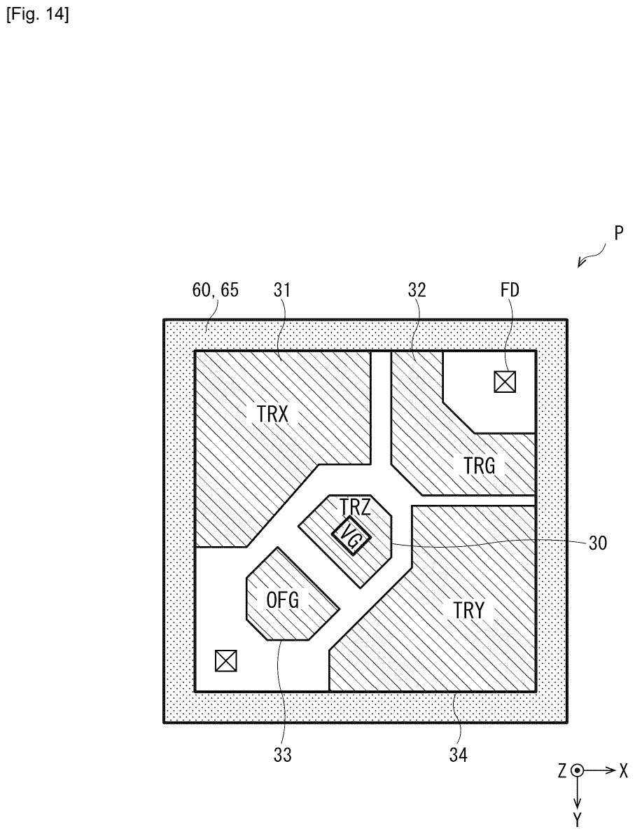

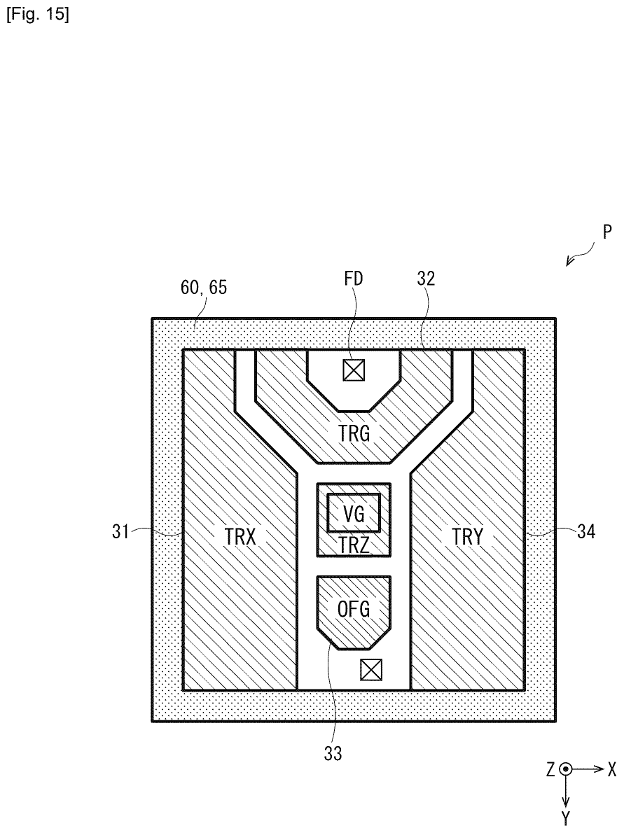

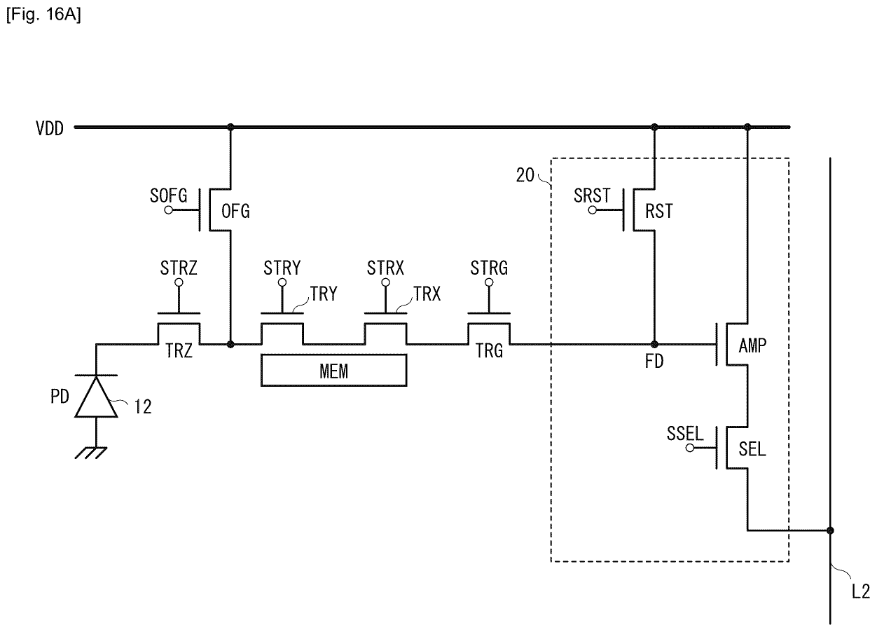

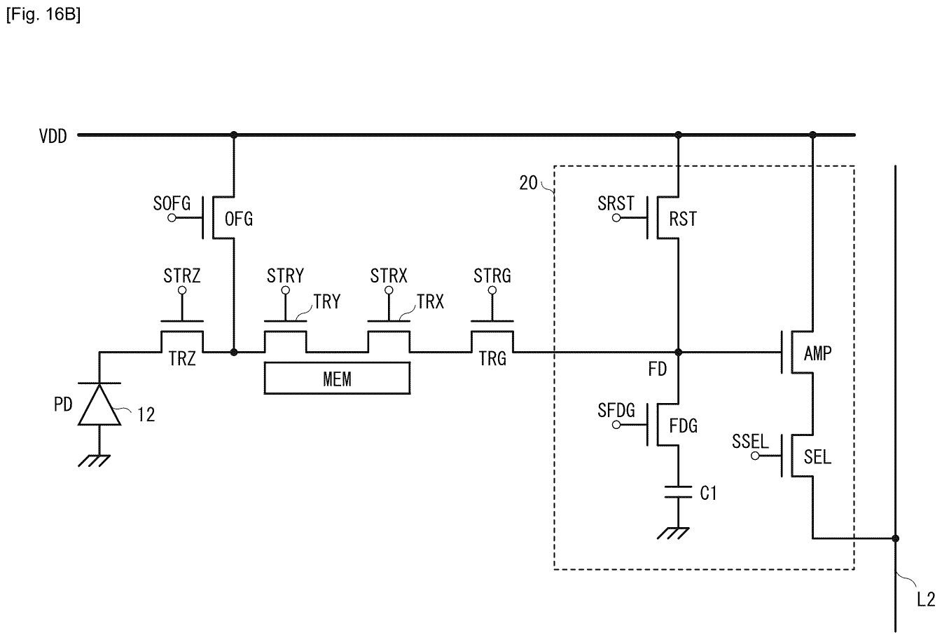

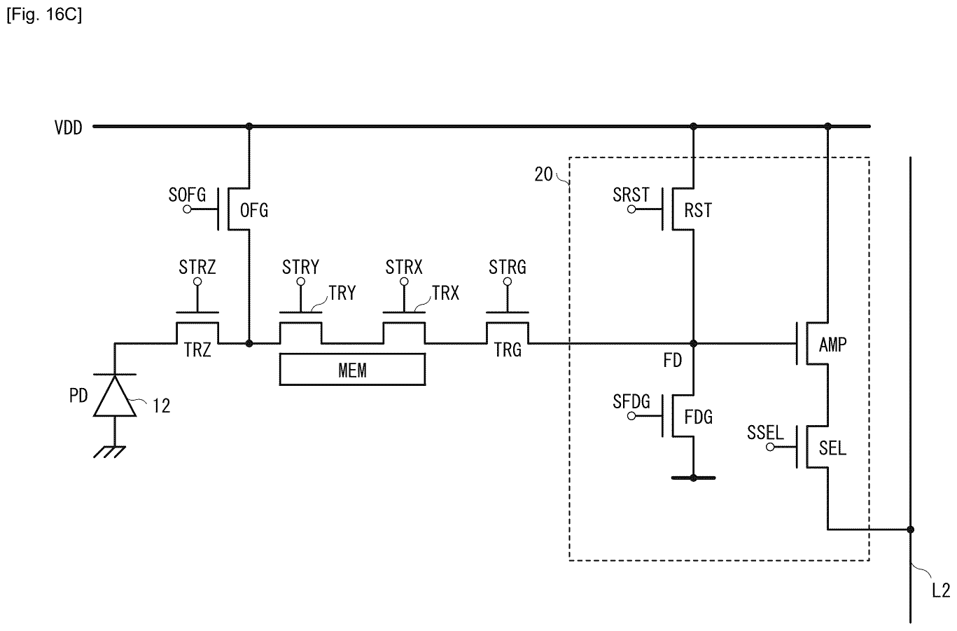

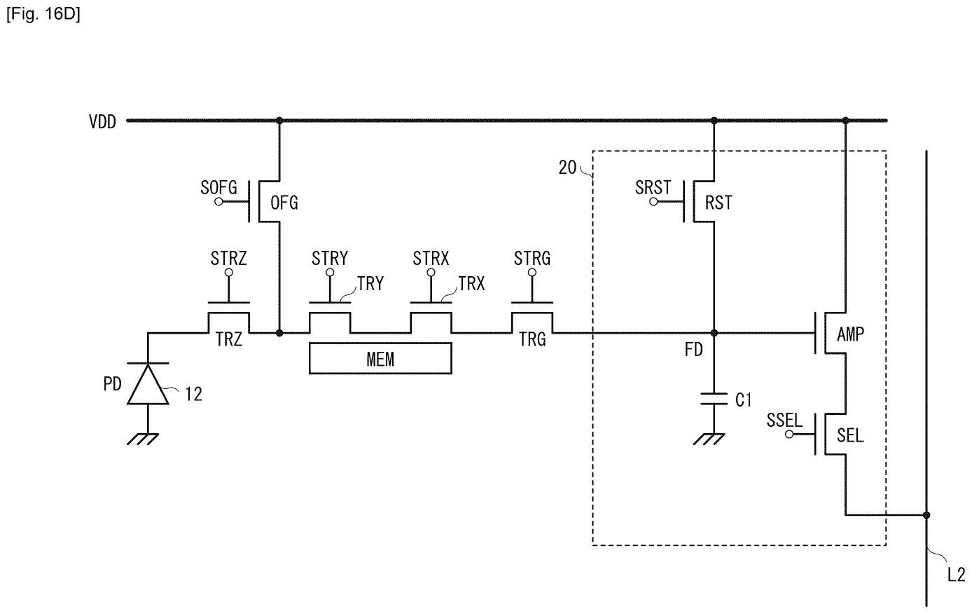

Although the above embodiment has been explained with regard to an example of the configuration of the pixel, the configuration of the pixel is not limited to the above example. FIG. 14 and FIG. 15 are diagrams each explaining an example of a configuration of a pixel of an imaging device according to Modification example 1 of the present disclosure. FIG. 16A is a diagram explaining an example of a circuit configuration of the pixel of the imaging device according to Modification example 1. For example, the pixel P may include a transistor TRY. The transistor TRY is configured to control a potential of the capacitor MEM. The transistor TRY is configured to adjust (change) a height of a potential barrier to prevent backflow of the electric charge from the capacitor MEM to the photoelectric conversion section 12, for example. The transistor TRY is referred to as a backflow prevention transistor.

As illustrated in FIG. 14 or FIG. 15, the plurality of elements including the transistor TRX, the transistor TRY, the transistor TRG, the transistor OFG, etc., is disposed around the transistor TRZ. The plurality of elements is provided to surround the transistor TRZ. In the case of the present modification example, because the gate electrode 30 of the transistor TRZ is provided in a region away from the separation part 60 in the semiconductor layer 10, it is also possible to prevent the strong electric field from being generated between the gate electrode 30 and the separation part 60. It is possible to suppress deterioration in the pixel signal quality.

Note that, as illustrated in an example illustrated in FIG. 16B, the pixel P may include a transistor FDG and a capacitor C1. The transistor FDG is configured to electrically couple the floating diffusion FD and the capacitor MEM to each other. For example, the transistor FDG is controlled by a signal SFDG, and electrically couples or decouples the floating diffusion FD and the capacitor C1 to or from each other.

The transistor FDG is a switching transistor used for setting of the conversion efficiency described above. The capacitor C1 is a capacitance (CI capacitance), for example formed by using an insulation film (for example, an oxide film). Note that, as in an example illustrated in FIG. 16C and FIG. 16D, the pixel P may include only one of the transistor FDG and the capacitor C1.

### 2-2. Modification Example 2

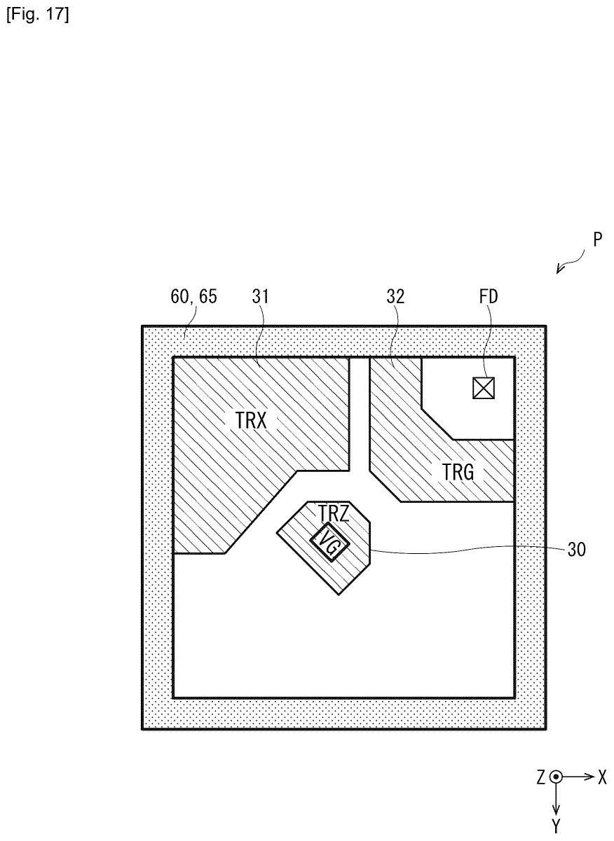

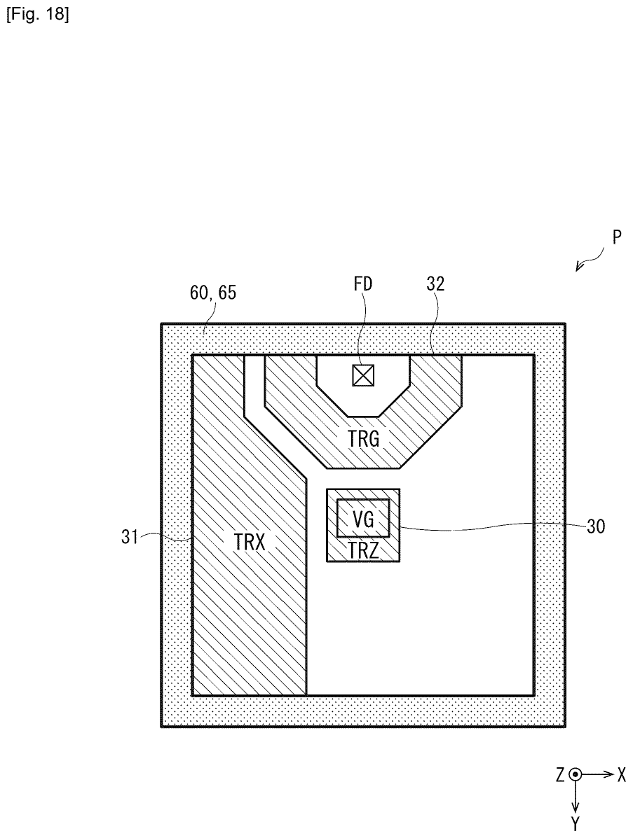

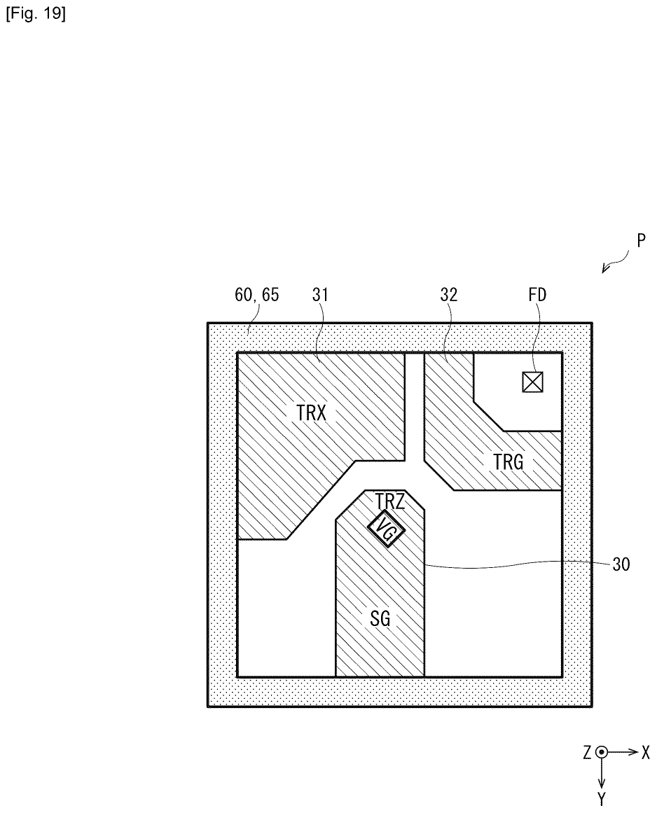

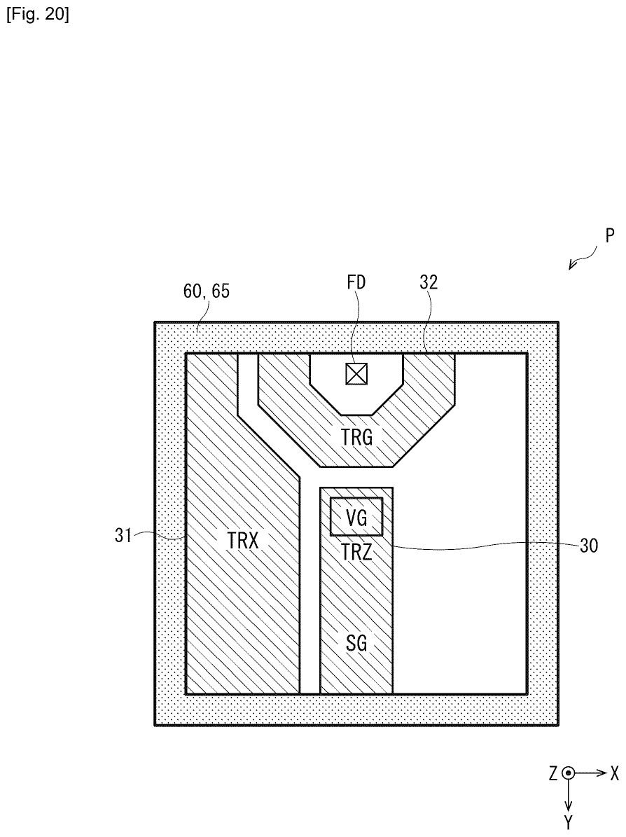

FIG. 17 to FIG. 20 are diagrams each explaining an example of a configuration of a pixel of an imaging device according to Modification example 2. As in an example illustrated in FIG. 17 or FIG. 18, the pixel P may be without the transistor OFG. Note that, with regard to the gate electrode 30 of the transistor TRZ of the pixel P, as in an example illustrated in FIG. 19 or FIG. 20, the second part SG, which is provided on the side of the second surface 11S2 of the semiconductor layer 10, may be provided to be in contact with the separation part 60.

### 2-3. Modification Example 3

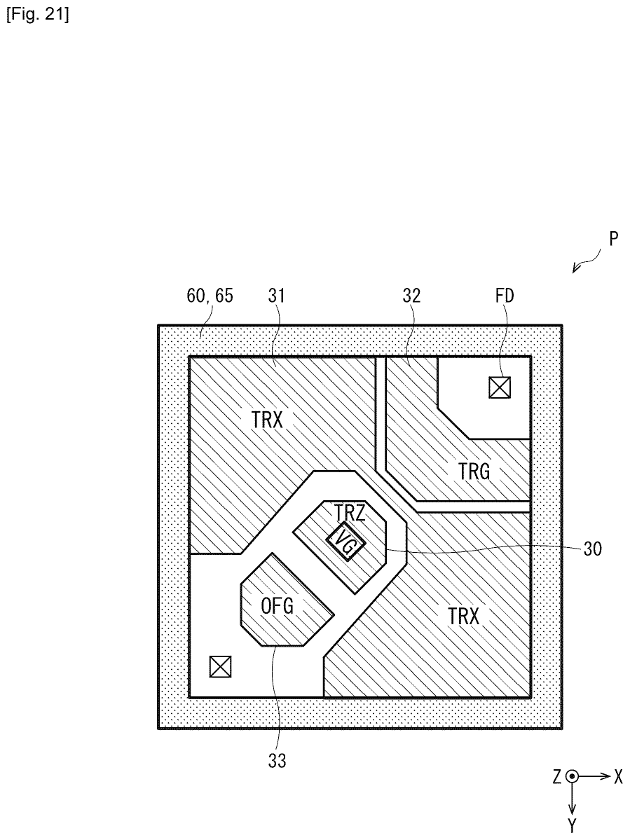

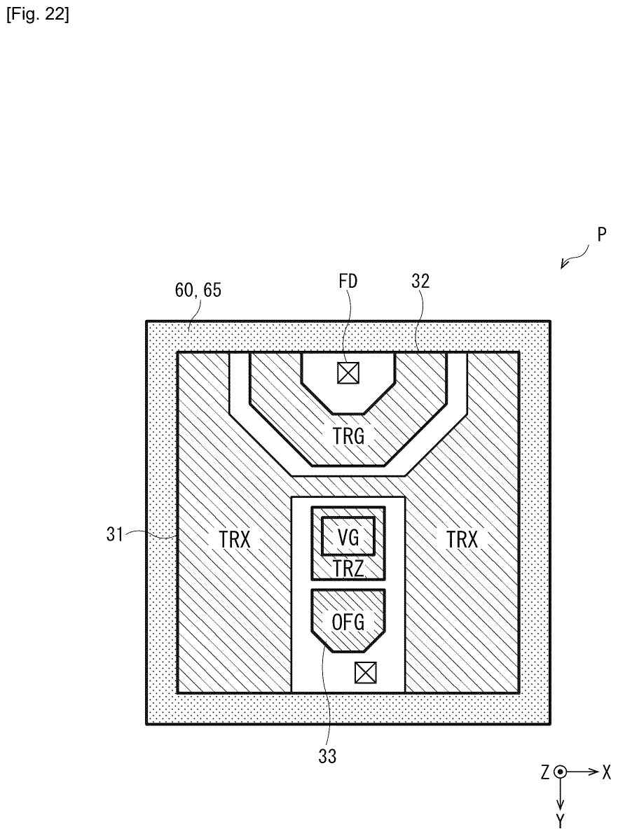

FIG. 21 and FIG. 22 are diagrams each explaining an example of a configuration of a pixel of an imaging device according to Modification example 3. An element, such as a transistor or a capacitor, may be provided between the transistor TRZ and the transistor TRG. For example, as in an example illustrated in FIG. 21 or FIG. 22, a part of the transistor TRX may be provided between the transistor TRZ and the transistor TRG. The transistor TRZ may be provided, for example, via a part of the transistor TRX, to be adjacent to the transistor TRG.

Note that an element other than the transistor TRX, for example, the transistor OFG, the transistor TRY, the transistor of the reading circuit 20, the capacitor (for example, the capacitor C1 described above), or the like may be provided between the transistor TRZ and the transistor TRG. In the case of the present modification example also, it is possible to achieve effects similar to those of the imaging device according to the above embodiments.

### 2-4. Modification Example 4

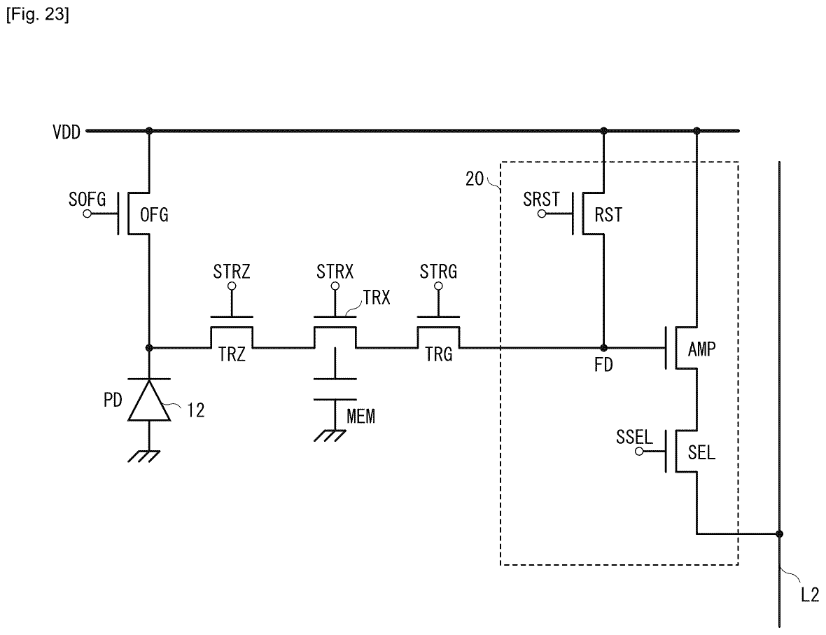

FIG. 23 is a diagram illustrating an example of a circuit configuration of a pixel of an imaging device according to Modification example 4. As illustrated in FIG. 23, the transistor OFG may be electrically coupled to the photoelectric conversion section 12. For example, the gate electrode 33 of the transistor OFG may be provided to reach the photoelectric conversion section 12 in the semiconductor layer 10. The transistor OFG is configured to reset the electric charge of the photoelectric conversion section 12, without involvement of the transistor TRZ, etc.

### 3. APPLICATION EXAMPLES

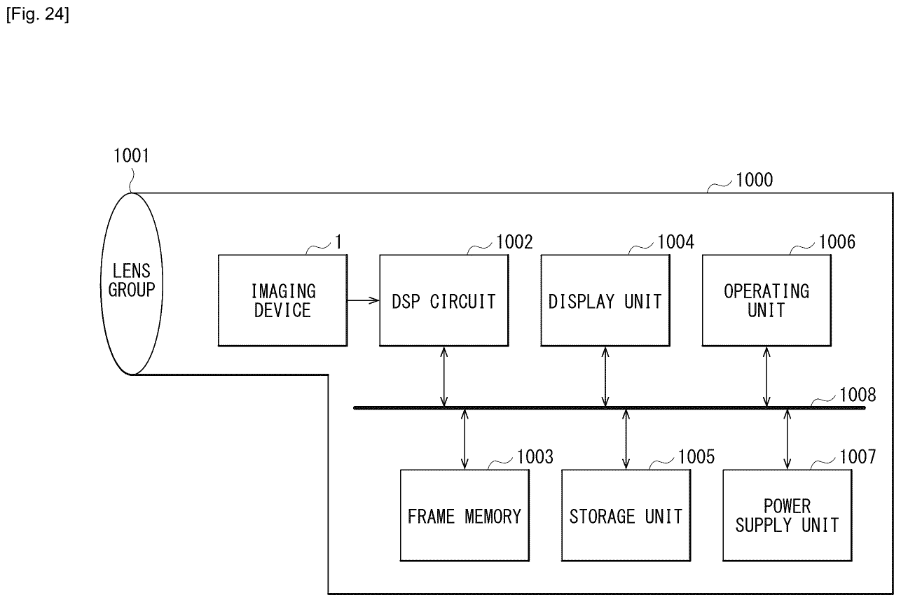

The imaging device 1, etc., may be applied to any type of electronic apparatus provided with image capturing functions, for example, a camera system such as a digital still camera or a video camera, or a mobile phone with image capturing functions. FIG. 24 illustrates an overall configuration of an electronic apparatus 1000.

The electronic apparatus 1000 includes, for example, a lens group 1001, the imaging device 1, a DSP (digital signal processor) circuit 1002, a frame memory 1003, a display unit 1004, a storage unit 1005, an operating unit 1006, and a power supply unit 1007, which are coupled to each other via a bus line 1008.

The lens group 1001 introduces entering light (image light) from a subject, and forms an image on an imaging plane of the imaging device 1. The imaging device 1 converts an amount of entering light, of which the image has been formed on the imaging plane by the lens group 1001, into electric signals by the unit of pixel, and supplies the electric signals to the DSP circuit 1002 as pixel signals.

The DSP circuit 1002 is a signal processing circuit that processes the signal supplied from the imaging device 1. The DSP circuit 1002 outputs image data acquired by processing of the signal from the imaging device 1. The frame memory 1003 temporarily stores the image data processed by the DSP circuit 1002, by the unit of frame.

The display unit 1004 includes, for example, a panel-type display device such as a liquid crystal panel or an organic EL (electro luminescence) panel, and records image data captured by the imaging device 1, such as moving images or still images, in a recording medium such as a semiconductor memory or hard disk.

The operating unit 1006 outputs operation signals for various functions of the electronic apparatus 1000 in accordance with operations by a user. The power supply unit 1007 supplies various types of electric power, serving as operation power sources for the DSP circuit 1002, the frame memory 1003, the display unit 1004, the storage unit 1005, and the operating unit 1006, to these targets of supply appropriately.

### 4. EXAMPLES OF PRACTICAL APPLICATION

### Example of Practical Application to Mobile Body

The technique according to the present disclosure (present technology) is applicable to a variety of products. For example, the technique according to the present disclosure may be achieved as a device mounted on any type of mobile body such as a vehicle, an electric vehicle, a hybrid electric vehicle, a motorcycle, a bicycle, a personal mobility, an airplane, a drone, a vessel, a robot, and the like.

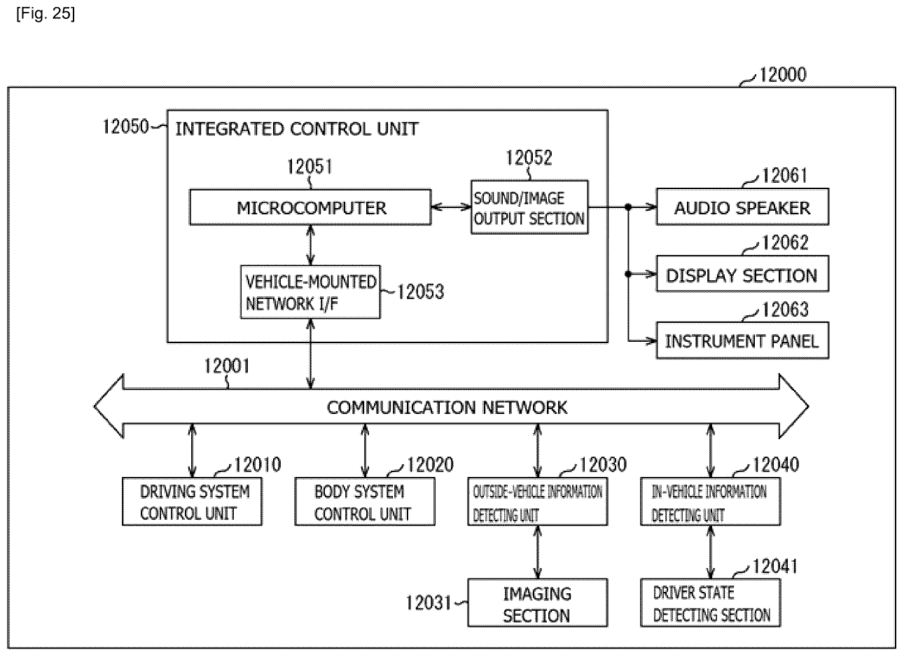

FIG. 25 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

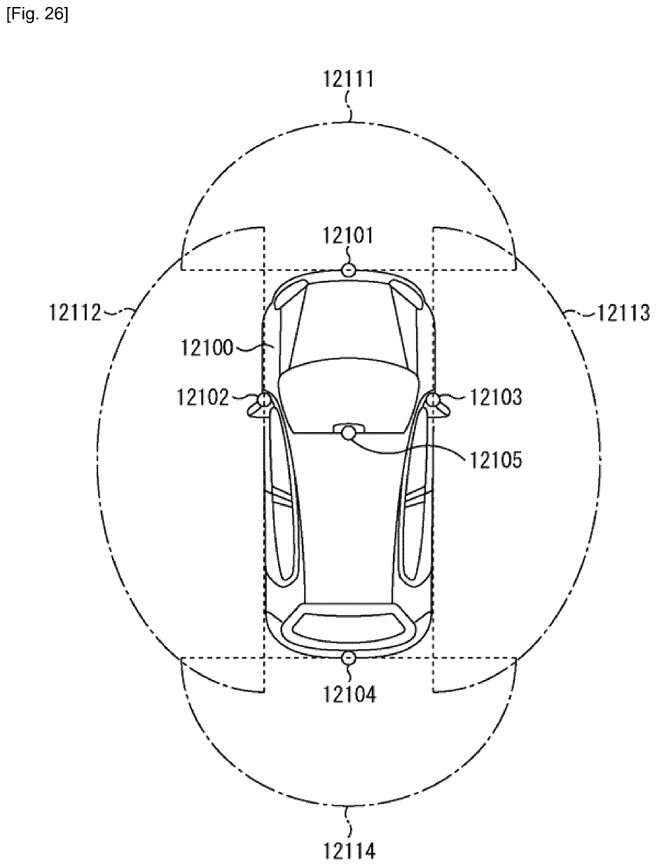

FIG. 26 is a diagram depicting an example of the installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the foregoing, described is one example of the mobile body control system to which the technique according to the present disclosure is applicable. The technique according to the present disclosure is applicable to the imaging section 12031 among the above-described components. Specifically, the imaging device 1 or the like is applicable to the imaging section 12031. The application of the technique according to the present disclosure to the imaging section 12031 makes it possible to obtain a high-definition captured image. It is thus possible to perform a highly accurate control with use of the captured image in the mobile body control system.

### Example of Practical Application to Endoscopic Surgery System

The technique according to the present disclosure (the present technology) is applicable to various products. For example, the technique according to the present disclosure may be applied to an endoscopic surgery system.

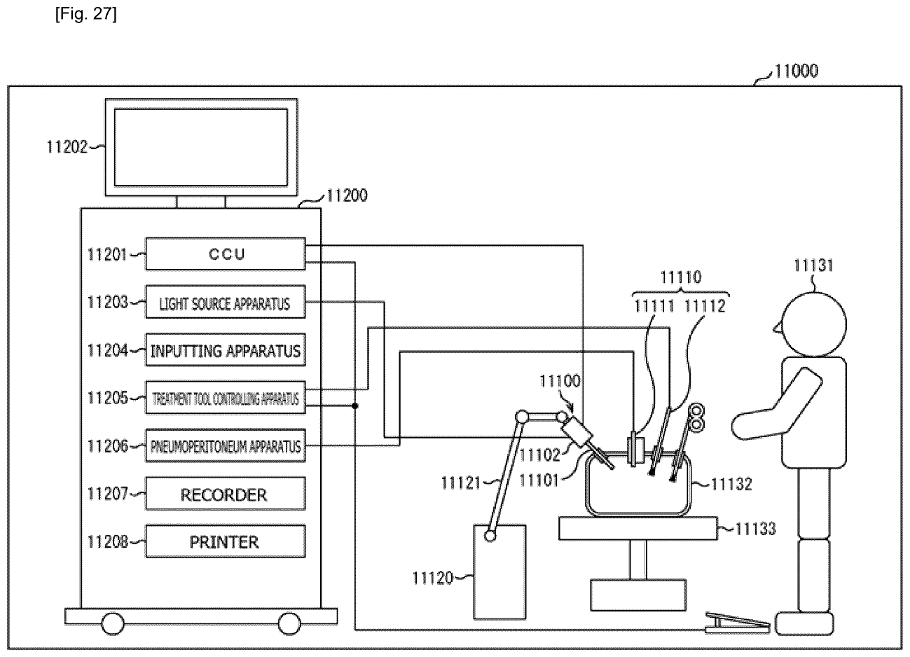

FIG. 27 is a view depicting an example of a schematic configuration of an endoscopic surgery system to which the technology according to an embodiment of the present disclosure (present technology) can be applied.

In FIG. 27, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

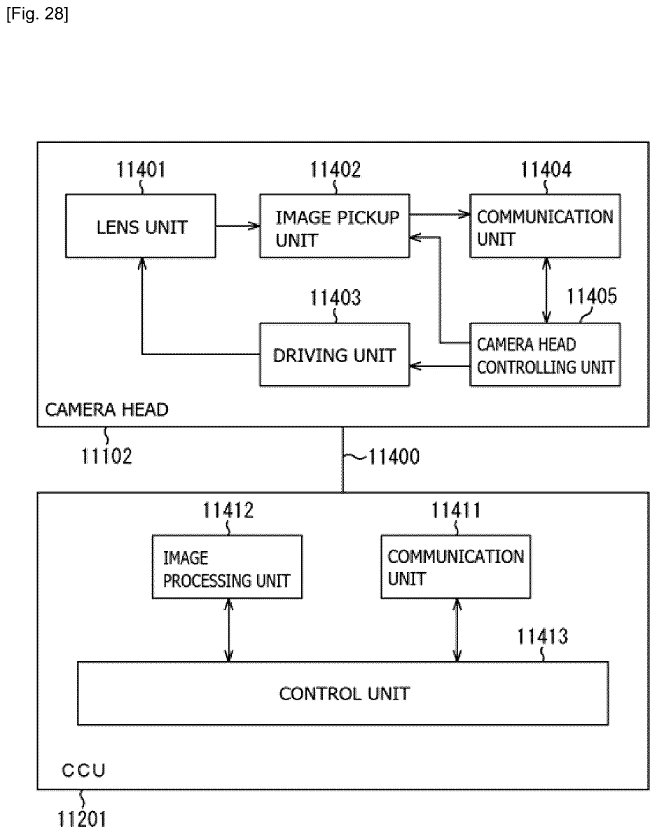

FIG. 28 is a block diagram depicting an example of a functional configuration of the camera head 11102 and the CCU 11201 depicted in FIG. 27.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

In the forgoing, described is one example of the endoscopic surgery system to which the technique according to the present disclosure is applicable. The technique according to the present disclosure is applicable to the imaging unit 11402 provided on the camera head 11102 of the endoscope 11100 among the above-described components. The application of the technique according to the present disclosure to the imaging unit 11402 makes it possible to provide the endoscope 11100 that is increased in definition.

Although the present disclosure has been described with reference to the embodiments, the modification examples, the application examples, and the practical application examples, the present technology is not limited to the above-described embodiments and the like, and various modifications are possible. For example, although the above modification examples have been explained as the modification examples of the embodiments described above, it is also possible to combine the configurations of these modification examples appropriately. For example, the present disclosure is not limited to backside-illuminated image sensors, and may also be applied to frontside-illuminated image sensors.

Although the present embodiments have been explained by exemplifying the imaging device, it is sufficient that the photodetector of the present disclosure receives the entering light and converts the light into the electric charge. The outputted signals may be image information signals, or distance measurement information signals. The photodetector (imaging device) may be applied to image sensors, distance measuring sensors, etc.

The photodetector according to the present disclosure may also be applied to a distance measuring sensor, configured to measure distance by using the TOF (time of flight) method. The photodetector (imaging device) may also be applied to sensors configured to detect events, for example, event-driven type of sensors (referred to as an EVS (event vision sensor), an EDS (event driven sensor), a DVS (dynamic vision sensor), etc.).

A photodetector according to an embodiment of the present disclosure includes a plurality of pixels and a separation part. The plurality of pixels includes a first pixel including a photoelectric converter provided in a semiconductor layer. The separation part is provided between the pixels adjacent to each other in the semiconductor layer. The first pixel includes a first transistor and a capacitor. The first transistor includes a first gate electrode, and is configured to transfer electric charge photoelectrically converted by the photoelectric converter. The first gate electrode is provided to reach the photoelectric converter in the semiconductor layer. The capacitor is provided to be stacked on the photoelectric converter, and is configured to accumulate the electric charge photoelectrically converted by the photoelectric converter. The first gate electrode is provided in a region away from the separation part in the semiconductor layer. Thus, it is possible to achieve the photodetector configured to suppress deterioration in the signal quality.

It should be noted that the effects described in this specification are only exemplified effects and non-limiting, and any other effect may be achieved. Moreover, the present disclosure may also be configured as follows.
(1)

A photodetector including:
a plurality of pixels including a first pixel including a photoelectric converter provided in a semiconductor layer; and
a separation part provided between the pixels adjacent to each other in the semiconductor layer, in which
the first pixel includes
   a first transistor including a first gate electrode, and configured to transfer electric charge photoelectrically converted by the photoelectric converter, the first gate electrode being provided to reach the photoelectric converter in the semiconductor layer, and
   a capacitor provided to be stacked on the photoelectric converter, and configured to accumulate the electric charge photoelectrically converted by the photoelectric converter, and
   the first gate electrode is provided in a region away from the separation part in the semiconductor layer.
(2)

The photodetector according to (1) described above, in which
the first pixel includes a floating diffusion and a second transistor that is configured to electrically couple the capacitor and the floating diffusion to each other, and
the first transistor is provided to be adjacent to the second transistor.
(3)

The photodetector according to (2) described above, further including
a plurality of elements including the second transistor, in which
the plurality of elements is provided to surround the first transistor.
(4)

The photodetector according to (3) described above, in which the separation part is provided, in a plan view, to surround the plurality of elements.
(5)

The photodetector according to any one of (2) to (4) described above, further including
a third transistor provided at a periphery of the first transistor, in which
at least a part of the third transistor is provided between the first transistor and the second transistor.
(6)

The photodetector according to any one of (2) to (5) described above, further including
a third transistor provided at a periphery of the first transistor, in which
the second transistor and the third transistor are provided to allow the first transistor to be interposed between the second transistor and the third transistor.
(7)

The photodetector according to any one of (2) to (6) described above, in which
the second transistor includes a second gate electrode provided on a side of a first surface of the semiconductor layer, and
the first gate electrode is provided, in a plan view, to be adjacent to the second gate electrode.
(8)

The photodetector according to (7) described above, in which the first gate electrode is provided to be adjacent to a side farthest from the separation part among a plurality of sides of the second gate electrode.
(9)

The photodetector according to (7) or (8) described above, in which a distance between the first gate electrode and the separation part is larger than a distance between the second gate electrode and the separation part.
(10)

The photodetector according to any one of (1) to (9) described above, in which at least a part of the first transistor is provided, in a plan view, on a diagonal line of the first pixel.
(11)

The photodetector according to any one of (1) to (10) described above, in which at least a part of the first gate electrode is provided, in a plan view, on a diagonal line of the first pixel.
(12)

The photodetector according to any one of (1) to (11) described above, in which
the first gate electrode includes a first part provided to reach the photoelectric converter in the semiconductor layer, and a second part provided on a side of a first surface of the semiconductor layer, and
a distance between the first part and the separation part is greater than or equal to one-third of a width of the first pixel.
(13)

The photodetector according to any one of (1) to (12) described above, in which at least a part of the first transistor is provided, in a plan view, at a center of the pixel.
(14)

The photodetector according to any one of (1) to (13) described above, in which
the first pixel includes a floating diffusion and a second transistor that is configured to electrically couple the capacitor and the floating diffusion to each other, and
the first gate electrode is at a position closer to a center of the pixel than the second transistor.
(15)

The photodetector according to (14) described above, further including
a third transistor provided at a periphery of the first transistor, in which
the first gate electrode is at a position closer to the center of the pixel than the second transistor and the third transistor.
(16)

The photodetector according to any one of (1) to (15) described above, further including
a light shielding part formed to be embedded in the semiconductor layer, in which
the light shielding part extends in a direction perpendicular to a thickness direction of the semiconductor layer.
(17)

The photodetector according to (16) described above, in which the light shielding part is not provided between the photoelectric converter and the capacitor.
(18)

The photodetector according to any one of (1) to (17) described above, in which
the semiconductor layer includes, a first surface, and a second surface on a side opposite to the first surface, and
the separation part is provided between the first surface and the second surface.
(19)

The photodetector according to any one of (1) to (18) described above, in which the separation part is provided to surround the photoelectric converter in the semiconductor layer.
(20)

An electronic apparatus including:
an optical system; and
a photodetector that receives light transmitted through the optical system,
the photodetector including
a plurality of pixels including a first pixel including a photoelectric converter provided in a semiconductor layer, and
a separation part provided between the pixels adjacent to each other in the semiconductor layer, in which
The First Pixel Includes
   a first transistor including a first gate electrode, and configured to transfer electric charge photoelectrically converted by the photoelectric converter, the first gate electrode being provided to reach the photoelectric converter in the semiconductor layer, and
   a capacitor provided to be stacked on the photoelectric converter, and configured to accumulate the electric charge photoelectrically converted by the photoelectric converter, and
the first gate electrode is provided in a region away from the separation part in the semiconductor layer.

The present application claims the benefit of Japanese Priority Patent Application JP2023-059433 filed with the Japan Patent Office on Mar. 31, 2023, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A photodetector comprising:
a plurality of pixels including a first pixel including a photoelectric converter provided in a semiconductor layer; and
a separation part provided between the pixels adjacent to each other in the semiconductor layer, wherein
the first pixel includes
a first transistor including a first gate electrode, and configured to transfer electric charge photoelectrically converted by the photoelectric converter, the first gate electrode being provided to reach the photoelectric converter in the semiconductor layer, and
a capacitor provided to be stacked on the photoelectric converter, and configured to accumulate the electric charge photoelectrically converted by the photoelectric converter, and
the first gate electrode is provided in a region away from the separation part in the semiconductor layer.

2. The photodetector according to claim 1, wherein
the first pixel includes a floating diffusion and a second transistor that is configured to electrically couple the capacitor and the floating diffusion to each other, and
the first transistor is provided to be adjacent to the second transistor.

3. The photodetector according to claim 2, further comprising
a plurality of elements including the second transistor, wherein
the plurality of elements is provided to surround the first transistor.

4. The photodetector according to claim 3, wherein the separation part is provided, in a plan view, to surround the plurality of elements.

5. The photodetector according to claim 2, further comprising
a third transistor provided at a periphery of the first transistor, wherein
at least a part of the third transistor is provided between the first transistor and the second transistor.

6. The photodetector according to claim 2, further comprising
a third transistor provided at a periphery of the first transistor, wherein
the second transistor and the third transistor are provided to allow the first transistor to be interposed between the second transistor and the third transistor.

7. The photodetector according to claim 2, wherein
the second transistor includes a second gate electrode provided on a side of a first surface of the semiconductor layer, and
the first gate electrode is provided, in a plan view, to be adjacent to the second gate electrode.

8. The photodetector according to claim 7, wherein the first gate electrode is provided to be adjacent to a side farthest from the separation part among a plurality of sides of the second gate electrode.

9. The photodetector according to claim 7, wherein a distance between the first gate electrode and the separation part is larger than a distance between the second gate electrode and the separation part.

10. The photodetector according to claim 1, wherein at least a part of the first transistor is provided, in a plan view, on a diagonal line of the first pixel.

11. The photodetector according to claim 1, wherein at least a part of the first gate electrode is provided, in a plan view, on a diagonal line of the first pixel.

12. The photodetector according to claim 1, wherein
the first gate electrode includes a first part provided to reach the photoelectric converter in the semiconductor layer, and a second part provided on a side of a first surface of the semiconductor layer, and
a distance between the first part and the separation part is greater than or equal to one-third of a width of the first pixel.

13. The photodetector according to claim 1, wherein at least a part of the first transistor is provided, in a plan view, at a center of the pixel.

14. The photodetector according to claim 1, wherein
the first pixel includes a floating diffusion and a second transistor that is configured to electrically couple the capacitor and the floating diffusion to each other, and
the first gate electrode is at a position closer to a center of the pixel than the second transistor.

15. The photodetector according to claim 14, further comprising
a third transistor provided at a periphery of the first transistor, wherein
the first gate electrode is at a position closer to the center of the pixel than the second transistor and the third transistor.

16. The photodetector according to claim 1, further comprising
a light shielding part formed to be embedded in the semiconductor layer, wherein
the light shielding part extends in a direction perpendicular to a thickness direction of the semiconductor layer.

17. The photodetector according to claim 16, wherein the light shielding part is not provided between the photoelectric converter and the capacitor.

18. The photodetector according to claim 1, wherein
the semiconductor layer includes, a first surface, and a second surface on a side opposite to the first surface, and
the separation part is provided between the first surface and the second surface.

19. The photodetector according to claim 1, wherein the separation part is provided to surround the photoelectric converter in the semiconductor layer.

20. An electronic apparatus comprising:
an optical system; and
a photodetector that receives light transmitted through the optical system,
the photodetector including
a plurality of pixels including a first pixel including a photoelectric converter provided in a semiconductor layer, and
a separation part provided between the pixels adjacent to each other in the semiconductor layer, wherein
the first pixel includes
a first transistor including a first gate electrode, and configured to transfer electric charge photoelectrically converted by the photoelectric converter, the first gate electrode being provided to reach the photoelectric converter in the semiconductor layer, and
a capacitor provided to be stacked on the photoelectric converter, and configured to accumulate the electric charge photoelectrically converted by the photoelectric converter, and
the first gate electrode is provided in a region away from the separation part in the semiconductor layer.
